(19) United States
(12) Patent Application Publication
(10) Pub. No.: US 2011/0303146 A1
(43) Pub. Date: Dec. 15, 2011

(54) PLASMA DOPING APPARATUS

(76) Inventors: Osamu Nishijima, Nara (JP); Yuichiro Sasaki, Nara (JP); Masafumi Kubota, Osaka (JP); Mototsugu Ogura, Nara (JP); Katsumi Okashita, Tokyo (JP)

(21) Appl. No.: 13/203,681

(22) PCT Filed: Dec. 2, 2010
(86) PCT No.: PCT/JP2010/007030

§ 371 Date: Aug. 26, 2011

(30) Foreign Application Priority Data
Dec. 28, 2009 (JP) 2009-296609

(51) Int. Cl. C23C 16/50; B05C 11/00

(52) U.S. Cl. 118/708; 118/723 R

(57) ABSTRACT

There is provided a regulating gas suction device, which forms a regulating gas flow for use in preventing air outside a vacuum container trying to invade into the vacuum container through a sealing member that tightly closes a gap between an upper end surface of the vacuum container and a peripheral edge of a top pate being opposed to each other from flowing toward a substrate at a coupling portion between the top plate and the vacuum container.

### TECHNICAL FIELD

The present invention relates to a plasma doping apparatus for use in introducing an impurity into a surface of a solid-state sample such as a semiconductor substrate.

### BACKGROUND ART

As a technique for introducing an impurity into a surface of a solid-state sample, a plasma doping method has been known in which an impurity is ionized and the ionized impurity is introduced into a solid-state material at low energy (for example, see Patent Document 1).

FIG. 11 illustrates a schematic structure of a plasma processing apparatus for used in the plasma doping method as a conventional impurity introducing method described in Patent Document 1 mentioned above. In FIG. 11, a sample electrode 202 on which a sample 201 made of a silicon substrate is placed is installed in a vacuum container 200. In the vacuum container 200, a gas supply device 203 for use in supplying a doping material gas containing a desired element, such as B₂H₆, and a pump 204 for reducing the pressure inside the vacuum container 200 are installed, so that the inside of the vacuum container 200 can be maintained at a predetermined pressure. A microwave is radiated from a microwave waveguide tube 205 into the vacuum container 200 through a quartz plate 206 serving as a dielectric window. By an interaction between this microwave and a DC magnetic field formed by an electromagnet 207, microwave plasma 208 with a magnetic field (electron cyclotron resonance plasma) is formed in the vacuum container 200. A high-frequency power supply 210 is connected to the sample electrode 202 with a capacitor 209 interposed therebetween so as to control the electric potential of the sample electrode 202. Here, a gas supplied from the gas supply device 203 is supplied into the vacuum container 200 through a gas blow-out hole 211, and is evacuated into the pump 204 through an exhaust port 212.

In the plasma processing apparatus having such a structure, the doping material gas, such as B₂H₆, supplied through the gas blow-out hole 211 is formed into plasma by a plasma generating means configured by the microwave waveguide tube 205 and the electromagnet 207, so that boron ions in the plasma 208 are introduced into the surface of the sample 201 upon application of high-frequency waves onto the sample electrode 202 by the high-frequency power supply 210.

After a metal wiring layer has been formed on the sample 201 into which an impurity is thus introduced, a thin oxide film is formed on the metal wiring layer in a predetermined oxidizing atmosphere. Thereafter, a gate electrode is formed on the sample 201 by a CVD device or the like so that, for example, an MOS transistor is obtained.

On the other hand, in the field of a general vacuum processing apparatus, various techniques have been disclosed so as to reduce the amount of leaking air from the environmental atmosphere into the vacuum processing apparatus (for example, see Patent Document 2). FIG. 12 shows a schematic structure of a conventional vacuum processing apparatus described in Patent Document 2 mentioned above, and FIG. 13 shows a sealing portion. In FIGS. 12 and 13, the vacuum container of the vacuum processing apparatus is configured by a plurality of members connected to each other. Out of two members 303a and 303b (an upper member and a lower member) adjacent to each other among these members, on a connecting end portion of the member 303a, a step portion is partially formed on an inner circumferential surface, with a convex portion 317 being formed on an outer circumferential side thereof, and on a connecting end portion of the other member 303b, a step portion is partially formed on an outer circumferential surface, with a concave portion 318 being formed on an outer circumferential side thereof. The member 303a and the other member 303b are connected to each other, with the convex portion 317 and the concave portion 318 being fitted to each other. Moreover, this structure is designed so that, between the convex portion 317 and the concave portion 318, an O-ring 316 is sandwiched so as to surround the entire circumference of the concave portion 318 of the other member 303b. In this manner, this structure is characterized in that the step portions are formed on the sealing portion. In FIG. 12, reference symbol 307 represents an evacuation unit, reference symbol 308 represents a deposited film forming space, reference symbol 312 represents a lid member, and reference symbol 313 represents a bottom surface member.

### PRIOR ART DOCUMENTS

### Patent Documents

Patent Document 1: U.S. Pat. No. 4,912,065
Patent Document 2: Japanese Unexamined Patent Publication No. 2002-241939

### SUMMARY OF THE INVENTION

### Issues to be Resolved by the Invention

In the conventional plasma processing apparatuses disclosed in Patent Documents 1, 2 mentioned above and the like, however, an issue arises in which it is difficult to reduce a sheet resistance of a diffusion layer formed by plasma doping.

It is an object of the present invention to provide a plasma doping apparatus that can form a diffusion layer having a low sheet resistance.

### Means for Resolving the Issue

In order to achieve the above object, the present inventors have examined the reasons why, upon application of the conventional plasma processing apparatus to a plasma doping process, it is not possible to form a diffusion layer having a low sheet resistance, and have obtained the following findings.

In this case, as the application of plasma doping, the present inventors have carried out examinations for reducing the sheet resistance in a manufacturing process for forming a source-drain extension region of a silicon device that requires an especially shallow diffusion layer. As the depth of the diffusion layer decreases, it becomes more difficult to reduce the sheet resistance. In the source-drain extension region of the silicon device, for example, in a case of a MOSFET having a half pitch of 32 nm and a gate length of 18 nm, required is a diffusion layer having a depth, as small as 9 nm, that is, 10 nm or less. Moreover, since it is very difficult to form such a shallow diffusion layer in a mass-production factory, a method has been known in which a portion referred to as “an off-set side wall spacer” is formed. In this method, the MOSFET can be operated even with use of a slightly deeper diffusion layer; however, even in this case, a very shallow diffusion layer of 20 nm or less is still required. These examinations make it possible to recognize problems that have not been noticeable from the examinations for trying to form the conventional diffusion layer not shallow to such an extent.

FIGS. 14A to 14H are partial cross-sectional views that show processes for forming a source-drain extension region of a planar device by plasma doping.

First, as shown in FIG. 14A, there is prepared an SOI substrate, which is formed by attaching a p-type silicon layer 263 onto the surface of a silicon substrate 261 with a silicon oxide film 262 interposed therebetween, and a silicon oxide film 264 serving as a gate oxide film is formed on the surface of the SOI substrate.

Then, as shown in FIG. 14B, a polycrystal silicon layer 265A for use in forming a gate electrode 265 is formed thereon.

Next, as shown in FIG. 14C, a mask R is formed thereon by a photolithography method.

Thereafter, as shown in FIG. 14D, the polycrystal silicon layer 265A and the silicon oxide film 264 are patterned by using the mask R so that a gate electrode 265 (see FIG. 14D) is formed.

Moreover, as shown in FIG. 14E, by using the gate electrode 265 as a mask, plasma doping is carried out to introduce arsenic thereto at a dosing amount of arsenic in a range of about 1 E15 cm⁻² to 4 E15 cm⁻² in such a manner that a layer of a shallow n-type impurity region 266 is formed.

Thereafter, as shown in FIG. 14F, after a silicon oxide film 267 is formed on the surface of the layer of the n-type impurity region 266 by a LPCVD (Low Pressure CVD) method, the silicon oxide film 267 is etched by anisotropic etching so that, as shown in FIG. 14G, the silicon oxide film 267 is left only on the side wall of the gate electrode 265.

By using the silicon oxide film 267 and the gate electrode 265 as masks, as shown in FIG. 14H, arsenic is injected by ion injection so that a source-drain region made of a layer of an n-type impurity region 268 is formed. Then, this layer is subjected to a heating treatment so that arsenic ions are activated.

In this manner, formed is a MOSFET in which a shallow layer of the n-type impurity region 266 is formed in the source-drain region made of the layer of the n-type impurity region 268.

At this time, in the process for forming the shallow layer of the n-type impurity region 266, plasma doping is carried out by using a plasma processing apparatus or the like disclosed in Patent Document 1 as shown in FIG. 11.

FIG. 15 illustrates an SIMS profile of arsenic in the source-drain extension region immediately after the injection in the case when the layer of the source-drain extension region has been formed by the plasma doping method with use of such a device, that is, the device shown in FIG. 11 as disclosed by Patent Document 1. In this case, the amount of dose of arsenic is 2.1 E15 cm⁻², with an injection depth (defined as a depth that obtains the arsenic concentration of 1 E18 cm⁻³) being set to 8.6 nm.

In the case when this is compared with an SIMS profile formed by an ion injection method, since the amount of dose of arsenic is 8 E14 cm⁻² with an injection depth being set to 12.2 nm in the case of adopting the ion injection method, it is found that the plasma doping method makes it possible to obtain a better SIMS profile having a larger amount of dose of arsenic with a smaller injection depth. This fact implies that, even in the case when the conventional plasma processing apparatus is used, the plasma doping method makes it possible to more easily form a diffusion layer shallower and having a lower sheet resistance in comparison with the case of adopting the ion injection method.

Therefore, arsenic was actually injected into a p-type silicon substrate by each of the plasma doping method and the ion injection method with use of the conventional plasma processing apparatus, and each of the substrates was subjected to an annealing process to allow arsenic to be electrically excited so that a shallow n-layer was formed. Then, the sheet resistance of the n-layer was measured by a four probe method, and by analyzing each of the diffusion depth by SIMS, Xj-Rs characteristics were obtained, and the Xj-Rs characteristics of the two layers were compared with each other.

Solid lines in FIG. 5 indicate the comparison between the Xj-Rs characteristics of the two layers. The solid lines of FIG. 5 indicate that the trend of the Xj-Rs characteristics obtained by the plasma doping method with use of the conventional plasma processing apparatus is superposed on that of the Xj-Rs characteristics obtained by the ion injection method (see a black square portion in FIG. 5). This state contradicts the aforementioned result after the annealing process implied by the SIMS profiles immediately after the injection, that is, the result indicating that the plasma doping method makes it possible to more easily form a diffusion layer shallower and having a lower sheet resistance, and indicates that, if the depth is substantially the same, only a diffusion layer having substantially the same sheet resistance can be formed, and that, if the depth is smaller, only a diffusion layer having a high sheet resistance can be formed.

In order to examine the cause of this fact, SIMS profiles after the annealing process were obtained. FIG. 16 shows the SIMS profiles of the n-layer after the annealing process formed by the plasma doping method with use of the conventional plasma doping apparatus. The diffusion depth (defined as a depth that obtains the arsenic concentration of 1 E18 cm⁻³) was 18.2 nm, and the sheet resistance was 542 Ω/sq. For reference, although not specifically shown, in the SIMS profiles of the n-layer after the annealing process formed by the ion injection method, the diffusion depth was 19.0 nm, and the sheet resistance was 502 Ω/sq.

By comparison of FIG. 16 with the SIMS profiles of the n-layer after the annealing process formed by the ion injection method, it was found that the largest difference lies in an oxygen profile. According to the SIMS profiles of the n-layer after the annealing process formed by the ion injection method, the depth of oxygen distribution was small, and the thickness of the oxide film, which is defined as a depth corresponding to a half of a peak value in a secondary ion intensity of oxygen, was 1 nm. On the other hand, in FIG. 16, the thickness of the oxide film was 3 nm, and the thickness of the oxide film obtained by the plasma doping method with use of the conventional plasma processing apparatus was thicker by about 2 nm. Since arsenic does not electrically form carriers in an oxide film and does not help to reduce the sheet resistance, it was thought that this thickly formed oxide film may cause no reduction in the sheet resistance by the plasma doping method with use of the conventional plasma processing apparatus.

In other words, in the case of the n-layer formed by the ion injection method, the region from the surface to a depth of about 15 nm has a high arsenic concentration exceeding 1 E20 cm⁻³, and this region mainly helps to reduce the sheet resistance; however, since the uppermost surface having about 1 nm in depth is the oxide film and allows no electricity to transmit therethrough, the remaining region having about 14 nm in depth allows electricity to easily flow therethrough.

In contrast, in the case of the n-layer formed by the plasma doping method with use of the conventional plasma processing apparatus of FIG. 16, the region from the surface to a depth of about 13 nm has a high arsenic concentration exceeding 1 E20 cm⁻³, and the arsenic concentration in this region is higher than the arsenic concentration of the n-layer formed by ion injection. For this reason, this region greatly helps to reduce the sheet resistance; however, the uppermost surface having about 3 nm in depth is the oxide film and allows no electricity to flow therethrough, with the result that the remaining region having about 10 nm in depth allows electricity to easily flow therethrough. In this manner, in the plasma doping method using the conventional plasma processing apparatus, it was considered that, although the region away from the surface by 3 nm or more to 13 nm or less can have a higher arsenic concentration than the case of adopting the ion injection method, only the trend of the Xj-Rs characteristics substantially the same as those of the ion injection method can be obtained because the region away from the surface by 1 nm or more to 3 nm or less has been formed into the insulating oxide film.

According to the above, the Xj-Rs characteristics that are superior to those obtained by the ion injection method are expected if the thickness of the oxide film can be made thinner. In view of the secondary ion intensity of oxygen immediately after the injection in FIG. 15, the thickness of an oxide film formed by the injection according to the ion injection method is 1.1 nm, while the thickness of the oxide film formed by the plasma doping method using the conventional plasma processing apparatus of FIG. 15 is 2.7 nm; thus, it was found that in the case of the plasma doping method using the conventional plasma processing apparatus, at the time after the injection is made (before the annealing process), a deep oxide film has already been formed. This implies that a large amount of oxygen is highly possibly injected without intention in the plasma doping process.

There was examined the reason why such a large amount of oxygen is injected in the plasma doping process.

The reason why amounts of leakage of oxygen and nitrogen are set to the same order as the amount of supply of AsH₃ is presumably that the leakage of air causes a large amount of oxygen to be injected without intention during the plasma doping process. This fact poses an issue in a process in which the plasma doping time is set to be as long as 45 seconds or more (in particular, 60 seconds or more) so as to ensure the reproducibility and uniformity, as well as in a process in which an AsH₃ concentration is set to a low level.

Based upon the above-mentioned findings, the present inventors have devised a plasma doping apparatus that can suppress influences of air leakage to the plasma doping process. In particular, the present invention mainly intends to direct air that has invaded into a vacuum container due to air leakage so as not to proceed toward a substrate, rather than to prevent the air leakage itself.

More specifically, in the present invention, there is provided a plasma doping apparatus including a regulating gas suction device, which forms a regulating gas flow for use in preventing a gas (for example, air) outside a vacuum container invading into the vacuum container by passing through a sealing member for tightly closing a gap between an upper end surface of the vacuum container and a contact surface of a top plate to the vacuum container being opposed to each other at a coupling portion between the top plate and the vacuum container from flowing toward a substrate.

That is, in one aspect of the present invention, there is provided a plasma doping apparatus comprising a sealing member that tightly closes a gap between an upper end surface of a vacuum container and a contact surface of a top plate to the vacuum container being opposed to each other, a suction groove that is formed in either one of the upper end surface of the vacuum container and the contact surface of the top place to the vacuum chamber being opposed to each other, along the entire circumference of the upper end portion of the vacuum container on an inner side of the vacuum container from the position of the sealing member, and a suction groove evacuation device that is connected to the suction groove and sucks a gas inside the suction groove so as to allow the pressure inside the suction groove to be lower than the pressure inside the vacuum container.

Moreover, in another aspect of the present invention, a plasma doping apparatus is provided in which an inner chamber is shaped to divide a space in the vacuum container at least on an upper side of a lower electrode, a gas passage is provided to allow a gas to flow into the divided space, and a gas supply device is provided to supply the gas into the gas passage.

In this case, the gas to be supplied into a dilution gas flow groove or the gas passage is preferably of the kind same as a dilution gas to be used in the plasma doping process. For example, in the case when a gas prepared by diluting AsH₃ with He is used in the plasma doping process, He is desirably used as the gas to be supplied into the dilution gas flow groove or the gas passage. Alternatively, in the case when a gas prepared by diluting AsH₃ with hydrogen is used in the plasma doping process, hydrogen is desirably used as the gas to be supplied into the dilution gas flow groove or the gas passage. The reason therefor is as follows: In the case when a gas of the kind same as the dilution gas is supplied into the dilution gas flow groove or the gas passage, it is possible to control influences onto the plasma doping process by controlling only the gas flow rate of the gas to be supplied. Further alternatively, in the case when the gas prepared by diluting AsH₃ with He is used in the plasma doping process, hydrogen may be used as the gas to be supplied into the dilution gas flow groove or the gas passage. Here, AsH₃ is decomposed in plasma to generate hydrogen ions. Thus, the hydrogen ions are present in the plasma during the plasma doping process; therefore, even when hydrogen of the same kind of element as those ions is supplied into the dilution gas flow groove or the gas passage, the influences onto the plasma doping process can be controlled by controlling only the gas flow rate of the gas to be supplied.

With this structure, air leaking into the vacuum container through the sealed gap between the upper end surface of the vacuum container and the contact surface of the top plate to the vacuum container can be directed to a gas suction device (suction groove evacuation device or gas evacuation device) together with the dilution gas such as helium. Therefore, by preventing the leaking air from invading toward the substrate in the vacuum container, suppress is doping of the substrate with oxygen derived from the leaking air. As a result, the oxide film on the surface of the substrate can be made thinner and the As concentration on the surface is made higher, thereby making it possible to obtain a superior effect of improvement of the Xj-Rs characteristics.

In order to achieve the above-mentioned object, the present invention has the following structures.

According to a first aspect of the present invention, there is provided a plasma doping apparatus comprising:

a vacuum container;

a top plate disposed on an upper end surface of the vacuum container;

a lower electrode disposed in the vacuum container and allowing a substrate to be placed thereon;

a high-frequency power supply that applies high-frequency power to the lower electrode;

a gas evacuation device that evacuates an inside of the vacuum container;

a gas supply device that supplies a process gas and a dilution gas into the vacuum container; and

a sealing member disposed between the upper end surface of the vacuum container and the top plate,

wherein on one of the upper end surface of the vacuum container and an contact surface of the top place to the vacuum chamber, a suction groove is disposed along an entire circumference of the vacuum container on an inner side to the vacuum container with respect to a position of the sealing member, and

a suction groove evacuation device connected to the suction groove is further included to suck a gas inside the suction groove to cause a pressure inside the suction groove to be made lower than a pressure inside the vacuum container.

According to a second aspect of the present invention, there is provided the plasma doping apparatus according to the first aspect, wherein the pressure inside the suction groove is reduced by at least one digit smaller than the pressure inside the vacuum container.

According to a third aspect of the present invention, there is provided the plasma doping apparatus according to the first or second aspect, further comprising:

a pressure detection device for the suction groove, which detects the pressure inside the suction groove;

a pressure detection device for the inside of the vacuum container, which detects the pressure inside the vacuum container; and

a control device that controls an operation of the gas evacuation device or the suction groove evacuation device such that the pressure inside the suction groove detected by the pressure detection device for a suction groove is made lower than the pressure inside the vacuum container detected by the pressure detection device for the vacuum container.

According to a fourth aspect of the present invention, there is provided the plasma doping apparatus according any one of the first to third aspects, wherein, outside the suction groove disposed in one of the upper end surface of the vacuum container and the contact surface of the top place to the vacuum chamber being opposed to each other, a dilution gas flow groove is disposed independently from the suction groove along an entire circumference of an upper end portion of the vacuum container, and

the plasma doping apparatus further comprising a dilution gas supply device that supplies a dilution gas to the dilution gas flow groove.

According to a fifth aspect of the present invention, there is provided the plasma doping apparatus according to the fourth aspect, wherein, outside the dilution gas flow groove disposed in one of the upper end surface of the vacuum container and the contact surface of the top place to the vacuum chamber being opposed to each other, an outer side suction groove is disposed independently from the dilution gas flow groove along the entire circumference of the upper end portion of the vacuum container, and an inside of the outer side suction groove is sucked by the suction groove evacuation device.

According to a sixth aspect of the present invention, there is provided a plasma doping apparatus comprising:

a vacuum container;

a top plate disposed on an upper end surface of the vacuum container;

a lower electrode disposed in the vacuum container and allowing a substrate to be placed thereon;

a high-frequency power supply that applies high-frequency power to the lower electrode;

a gas evacuation device that evacuates an inside of the vacuum container;

a gas supply device that supplies a process gas and a dilution gas into the vacuum container;

an inner chamber disposed in the vacuum container and along an inner wall surface of the vacuum container;

a dilution gas passage formed by the inner wall surface of the vacuum container and the inner chamber; and

a dilution gas supply device that supplies a dilution gas to the dilution gas passage from the top plate toward an evacuation side.

According to a seventh aspect of the present invention, there is provided the plasma doping apparatus according to the sixth aspect, wherein the vacuum container is configured by an upper chamber provided with the top plate on an upper end thereof and a lower chamber located under the upper chamber and coupled to the upper chamber.

According to an eighth aspect of the present invention, there is provided the plasma doping apparatus according to the sixth or seventh aspect, wherein the dilution gas passage has a gas flow passage of a length set to a mean free path or more.

According to a ninth aspect of the present invention, there is provided the plasma doping apparatus according to any one of the first to eighth aspects, wherein the processing gas is AsH₃.

According to a tenth aspect of the present invention, there is provided the plasma doping apparatus according to any one of the first to eighth aspects, wherein the dilution gas is helium, hydrogen, or neon.

### Effects of the Invention

In accordance with the present invention, by making the pressure inside the suction groove lower than the pressure inside the vacuum container, the gas inside the vacuum container is sucked into the suction groove, so that a gas flow is formed from the inside of the vacuum container toward the inside of the suction groove between the upper end surface of the vacuum container and the contact surface of the top plate to the vacuum container being opposed to each other. By using this gas flow, air proceeding from the outside of the vacuum container into the vacuum container can be blocked, so that the air is sucked into the suction groove. Alternatively, there is formed a gas passage through which a gas is allowed to flow in a space formed by dividing the space of the vacuum container by an inner chamber, so that air proceeding from the outside of the vacuum container into the vacuum container is directed toward an evacuation side by the gas flow and the air is prevented from proceeding toward the substrate.

Therefore, by preventing the air leaking into the vacuum container from invading toward the substrate in the vacuum container, it is possible to suppress doping of the substrate with oxygen derived from the leaking air. As a result, the oxide film on the surface of the substrate can be made thinner and the As concentration on the surface is made higher, thereby making it possible to obtain the superior effect of improvement of the Xj-Rs characteristics. It is therefore possible to provide a plasma doping apparatus capable of producing a semiconductor device with a large on-state current.

### BRIEF DESCRIPTION OF THE DRAWINGS

These and other aspects and features of the present invention will become clear from the following description taken in conjunction with the preferred embodiments thereof with reference to the accompanying drawings, in which:

FIG. 1A is a partial cross-sectional view showing a plasma doping apparatus in accordance with a first embodiment of the present invention;

FIG. 1B is a bottom view showing a top plate of the plasma doping apparatus;

FIG. 1C is a plan view showing an inner chamber of the plasma doping apparatus;

FIG. 2 is a partially enlarged cross-sectional view showing the inner chamber, a gas passage, a gas supplying device for the gas passage, and the like in the plasma doping apparatus used in the first embodiment of the present invention;

FIG. 3A is a view for explaining comparisons between main numerical values in the SIMS profiles of As each in a surface region of a silicon substrate immediately after injection, in a first working example and a comparative example of the first embodiment;

FIG. 3B illustrates the SIMS profile of As in the surface region of the silicon substrate immediately after the injection in the first working example;

FIG. 3C illustrates the SIMS profile of As in the surface region of the silicon substrate immediately after the injection in the comparative example;

FIG. 4 illustrates an SIMS profile of As after an annealing process;

FIG. 5 is a graph showing the comparisons of Xj-Rs characteristics obtained by evaluation of diffusion depths (Xj) and sheet resistances (Rs) of two n-layers that are respectively formed on surfaces of silicon substrates by using the plasma doping apparatus of the first working example and a plasma doping apparatus of the comparative example (which is provided with none of a gas passage, a gas blow-out hole, and a gas supplying device for a gas passage) under same plasma doping conditions;

FIG. 6 is a partial cross-sectional view showing a plasma doping apparatus in accordance with a second embodiment of the present invention;

FIG. 7 is a partially enlarged cross-sectional view showing a suction groove of a coupling end of a vacuum container and a regulating gas suction device in the plasma doping apparatus used in the second embodiment of the present invention;

FIG. 8 is a plan view showing a lower chamber of the vacuum container of the plasma doping apparatus used in the second embodiment of the present invention;

FIG. 9 is a partially enlarged cross-sectional view for explaining a modified example of the second embodiment of the present invention;

FIG. 10 is a partially enlarged cross-sectional view for explaining another modified example of the second embodiment of the present invention;

FIG. 11 is a view showing a schematic structure of a plasma processing apparatus used in a plasma doping method as a conventional impurity-introducing method described in Patent Document 1;

FIG. 12 is a view showing a schematic structure of a conventional vacuum processing apparatus described in Patent Document 2;

FIG. 13 is a view showing a sealing portion of the vacuum processing apparatus of FIG. 12;

FIG. 14A is a partial cross-sectional view showing a process for forming a source-drain extension region of a planar device by plasma doping;

FIG. 14B is a partial cross-sectional view showing a process for forming the source-drain extension region of the planar device by plasma doping;

FIG. 14C is a partial cross-sectional view showing a process for forming the source-drain extension region of the planar device by plasma doping;

FIG. 14D is a partial cross-sectional view showing a process for forming the source-drain extension region of the planar device by plasma doping;

FIG. 14E is a partial cross-sectional view showing a process for forming the source-drain extension region of the planar device by plasma doping;

FIG. 14F is a partial cross-sectional view showing a process for forming the source-drain extension region of the planar device by plasma doping;

FIG. 14G is a partial cross-sectional view showing a process for forming the source-drain extension region of the planar device by plasma doping;

FIG. 14H is a partial cross-sectional view showing a process for forming the source-drain extension region of the planar device by plasma doping;

FIG. 15 is a graph showing an SIMS profile of arsenic in a source-drain extension region immediately after injection in the case when a layer of the source-drain extension region is formed by the plasma doping method with use of an apparatus shown in FIG. 11, as disclosed in Patent Document 1; and

FIG. 16 is a graph showing SIMS profiles of an n layer after annealing in the case when the layer is formed by the plasma doping method with use of a conventional plasma processing apparatus.

### DESCRIPTION OF EMBODIMENTS

Before the description of the present invention proceeds, it is to be noted that like parts are designated by like reference numerals throughout the accompanying drawings.

Referring to the drawings, the following description will refer to embodiments of the present invention.

### First Embodiment

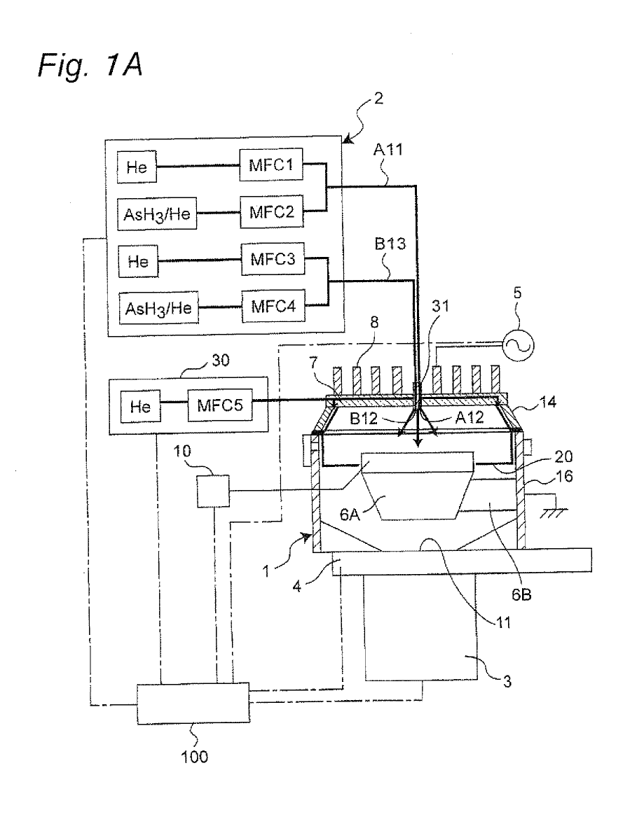

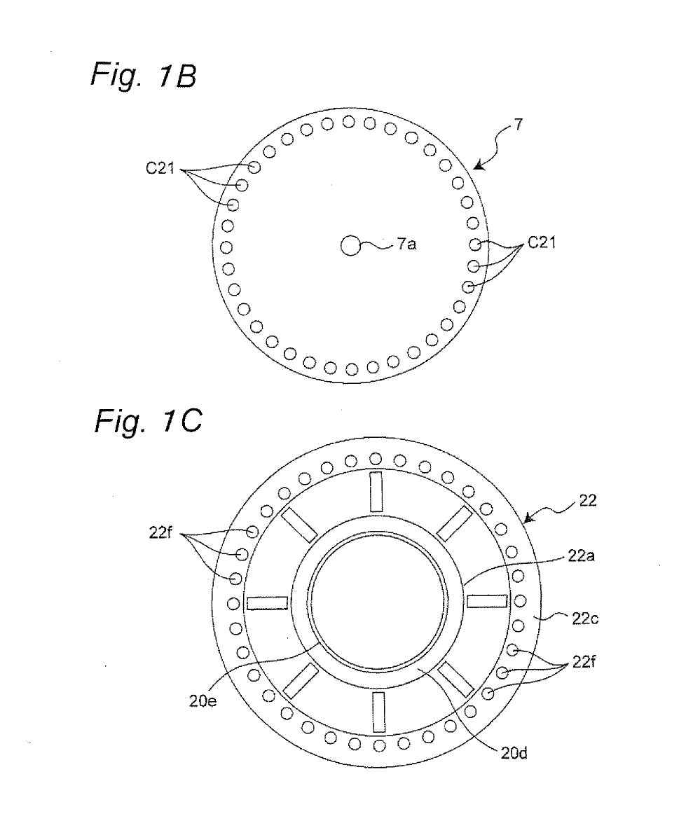

Referring to FIGS. 1A to 5, the following description will refer to a first embodiment of the present invention.

FIG. 1A is a partial cross-sectional view showing a plasma doping apparatus for use in the first embodiment of the present invention. FIG. 1B is a bottom view showing a top plate 7 of the plasma doping apparatus, and FIG. 1C is a plan view showing an inner chamber 20 of the plasma doping apparatus.

In FIGS. 1A to 1C, while a predetermined gas is being introduced from a gas supply device 2 into a vacuum container 1 that is provided with the top plate 7 on an upper opening in an upper end surface and is grounded, evacuation is performed by a turbo molecular pump 3 serving as an example of a gas evacuation device, and the inside of the vacuum container 1 can be maintained at a predetermined pressure by a pressure adjusting valve 4. A high-frequency power supply 5 for a coil is used for supplying, with high frequency power of 13.56 MHz, a coil 8 that serves as one example of an upper electrode and is formed near a dielectric window (dielectric window member) 7 serving as one example of the top plate so as to face a sample electrode 6, so that plasma can be generated in the vacuum container 1. A silicon substrate 9 as a sample is placed on the sample electrode 6. A high-frequency power supply 10 for a sample electrode used for supplying high frequency power to the sample electrode 6 is installed. This high-frequency power supply 10 for a sample electrode functions as a voltage source that controls the electric potential of the sample electrode 6 so as to allow the substrate 9 serving as the sample to maintain a negative electric potential relative to plasma.

In this manner, ions in the plasma are accelerated toward the surface of the sample to collide therewith so that impurities can be introduced into the surface of the substrate 9 as the sample.

In this case, the gas supplied from the gas supply device 2 is evacuated into the pump 3 through an exhaust port 11. The turbo molecular pump 3 and the exhaust port 11 are disposed right below the sample electrode 6 serving as one example of a lower electrode or a substrate electrode. The sample electrode 6 is a seat having a substantially round shape on which the substrate 9 is placed. The sample electrode 6 is supported by an insulating support base 6A, and the support base 6A is secured onto an inner wall of the vacuum container 1 by a support member 6B so as to be disposed in the center in the vacuum container 1.

A gas is supplied from the gas supply device 2 into a gas introduction path All that connects the gas supply device 2 and the inside of the vacuum container 1 in the following manner. The flow rate of a gas containing an impurity material gas is controlled to a predetermined value by first and second flow-rate control devices (mass flow controllers) MFC1 and MFC2 installed in the gas supply device 2. In general, a gas prepared by diluting the impurity material gas with helium, such as a gas prepared by diluting arsine (AsH₃) to 2% with helium (He), is used as the impurity material gas serving as one example of a process gas, and the flow rate of this gas is controlled by the second mass flow controller MFC2. Moreover, the flow rate of helium serving as one example of the dilution gas is controlled by the first mass flow controller MFC1, and the gases (helium and the impurity material gas) of which flow rates have been controlled by the first and second mass flow controllers MFC1 and MFC2 are mixed with each other in the gas supply device 2. Thereafter, the mixed gas is introduced into the vacuum container 1 through a gas blow-out hole A12 of a gas injector 31 by way of the gas introduction path A11, and further by way of the gas injector 31 that is secured to the dielectric window 7 in a manner so as to pass through a through hole 7a provided in the center of the dielectric window 7. The gas blow-out hole A12 is designed to blow gas toward the center of the substrate 9 from the surface opposed to the substrate 9.

In the same manner, into a gas introduction path B13 that connects the gas supply device 2 with the inside of the vacuum container 1, a gas is supplied from the gas supply device 2 in the following manner. The flow rate of a gas containing an impurity material gas is controlled to a predetermined value by third and fourth flow-rate control devices (mass flow controllers) MFC3 and MFC4 installed in the gas supply device 2. In general, a gas prepared by diluting the impurity material gas with helium, such as a gas prepared by diluting arsine (AsH₃) to 2% with helium (He), is used as the impurity material gas serving as one example of a process gas, and the flow rate of this gas is controlled by the fourth mass flow controller MFC4. Moreover, the flow rate of helium serving as one example of the dilution gas is controlled by the third mass flow controller MFC3, and the gases (helium and the impurity material gas) of which flow rates have been controlled by the third and fourth mass flow controllers MFC3 and MFC4 are mixed with each other in the gas supply device 2, and the mixed gas is then introduced into the vacuum container 1 through a gas blow-out hole B12 of the gas injector 31 by way of the gas introduction path B13, and further by way of the gas injector 31 that is secured to the dielectric window 7 in a manner so as to pass through the center of the dielectric window 7. The gas blow-out hole B12 is designed to blow the gas toward the peripheral edge of the substrate 9 from the surface opposed to the substrate 9.

There is also provided a control device 1000, which is connected to the gas supply device 2, the pump 3, the pressure adjusting valve 4, the high-frequency power supply 5 for a coil, and the high-frequency power supply 10 for a sample electrode. Thus, the operations of the gas supply device 2, the pump 3, the pressure adjusting valve 4, the high-frequency power supply 5 for a coil, and the high-frequency power supply 10 for a sample electrode are respectively controlled by the control device 1000.

One of the features of the first embodiment in the present invention is that there is provided the inner chamber 20, which is disposed further inside the vacuum container 1 located at least above the sample electrode 6 so as to be close to the inner wall of the vacuum container 1. Another feature of the first embodiment is that gas passages C22a and C22b on the upper and lower sides are each formed as one example of a dilution gas passage, between the inner chamber 20 and chambers, for example, two chambers 14 and 16, and that there is provided a gas supply device 30 for a gas passage used for supplying a gas to the gas passages C22a and C22b. The gas supply device 30 for a gas passage is also connected to the control device 1000 so that the operation of the gas supply device 30 for a gas passage is also controlled by the control device 1000. In FIG. 1A, for example, the vacuum container 1 is constituted by an upper chamber 14 provided with the top plate 7 on an upper end thereof, and a lower chamber 16 located below the upper chamber 14. Also provided is the inner chamber 20, which is disposed further inside the upper chamber 14 and the lower chamber 16, so as to be close to these two chambers 14 and 16. The present invention is not intended to be limited to this structure, and the upper chamber 14 and the lower chamber 16 may be formed integrally with each other, or, in contrast, the vacuum container 1 may be divided into three or more portions.

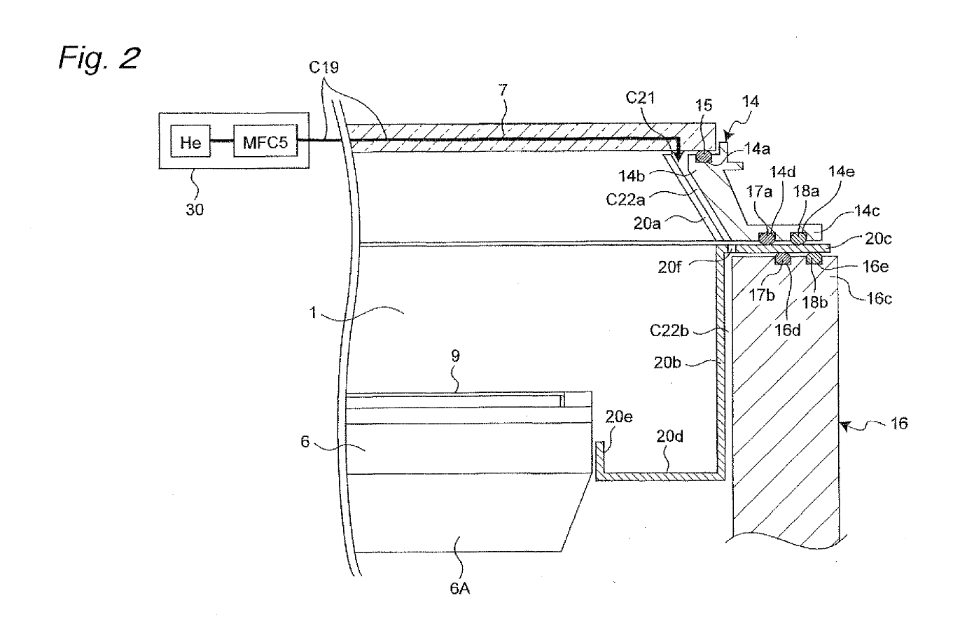

FIG. 2 is a partially enlarged cross-sectional view illustrating the shape of the inner chamber 20, the gas passages C22a and C22b formed by the inner chamber 20 and the lower chamber 16, the gas supply device 30 for a gas passage used for supplying a gas to the gas passages C22a and C22b, and the like in the plasma doping apparatus used in the first embodiment of the present invention.

In FIG. 2, the upper chamber 14 is placed so as to support the peripheral edge of the dielectric window 7 by the end surface of a coupling end portion 14b thereabove.

The peripheral edge of the dielectric window 7 and the coupling end portion 14b of the upper chamber 14 are tightly joined to each other to be sealed, with a vacuum-sealing O-ring 15 that is disposed in a first concave groove 14a formed in a circular ring shape in the end surface of the coupling end portion 14b of the upper chamber 14, being interposed therebetween. With this structure, reduced is the amount of air invading into the vacuum container 1 from the outside of the vacuum container 1 through a gap between the upper chamber 14 and the dielectric window 7.

A disc-shaped flange portion 20c that extends outward from the middle portion of the inner chamber 20 is sandwiched between a lower coupling end portion 14c of the upper chamber 14 and an upper coupling end portion 16c of the lower chamber 16 and tightened to be secured therein. Thus, the inner chamber 20 is secured by the upper chamber 14 and the lower chamber 16.

The lower coupling end portion 14c of the upper chamber 14 and the disc-shaped flange portion 20c of the inner chamber 20 are tightly joined to each other to be sealed, with a vacuum-sealing O-ring 17a that is disposed in a second concave groove 14d formed in a circular ring shape in the end surface of the lower coupling end portion 14c of the upper chamber 14, being interposed therebetween. With this structure, reduced is the amount of air invading into the vacuum container 1 from the outside of the vacuum container 1 through a gap between the lower coupling end portion 14c of the upper chamber 14 and the disc-shaped flange portion 20c of the inner chamber 20.

Moreover, the upper coupling end portion 16c of the lower chamber 16 and the disc-shaped flange portion 20c of the inner chamber 20 are tightly joined to each other to be sealed, with a vacuum-sealing O-ring 17b that is disposed in a first concave groove 16d formed in a circular ring shape in the end surface of the upper coupling end portion 16c of the lower chamber 16, being interposed therebetween. With this structure, reduced is the amount of air invading into the vacuum container 1 from the outside of the vacuum container 1 through a gap between the upper coupling end portion 16c of the lower chamber 16 and the disc-shaped flange portion 20c of the inner chamber 20.

Furthermore, the lower coupling end portion 14c of the conductive upper chamber 14 and the disc-shaped flange portion 20c of the conductive inner chamber 20 are electrically conductive to each other by a conductive metal coil 18a for use in grounding, which is disposed on the end surface of the lower coupling end portion 14c of the upper chamber 14 so as to be located outside the second concave groove 14d and located inside a third concave groove 14e formed into a circular ring shape.

Furthermore, the disc-shaped flange portion 20c of the conductive inner chamber 20 and the upper coupling end portion 16c of the conductive lower chamber 16 are electrically conductive to each other by a conductive metal coil 18b for use in grounding, which is disposed on the end surface of the upper coupling end portion 16c of the lower chamber 16 so as to be located outside the first concave groove 16d and disposed inside a second concave groove 16e formed into a circular ring shape.

Consequently, since the lower chamber 16 is grounded, the inner chamber 20 and the upper chamber 14 are also grounded through the metal coil 18b and the metal coil 18a.

In this case, the inner chamber 20 is formed into a structure in which an upper cone-shaped cylinder portion 20a that is tilted substantially in parallel with the inner wall of the upper chamber 14 in a manner so as to extend along the inner wall of the upper chamber 14, a lower cylinder portion 20b that is disposed substantially in parallel with the inner wall of the lower chamber 16 in a manner so as to extend along the inner wall of the lower chamber 16, a circular ring-shaped inner flange portion 20d that protrudes toward the sample electrode 6 from the lower end of the lower cylinder portion 20b, and an upright portion 20e that rises upward from the inner end of the inner flange portion 20d are integrally formed. On the inner end side of the disc-shaped flange portion 20c in the intermediate portion of the inner chamber 20, a large number of through holes 20f are disposed so that the upper gas passage C22a and the lower gas passage C22b, which will be described later, are allowed to communicate with each other. The upper gas passage C22a is formed in a space between the outer surface of the upper cone-shaped cylinder portion 20a of the inner chamber 20 and the inner wall of the upper chamber 14. Moreover, the lower gas passage C22b is formed in a space between the outer surface of the lower cylinder portion 20b of the inner chamber 20 and the inner wall of the lower chamber 16. In this structure, the width of each of the upper and lower gas passages C22a and C22b is set to, for example, 10 mm or less as well as to 0.01 mm or more. When the width of each of the gas passages C22a and C22b exceeds 10 mm, an abnormal discharge tends to be generated. In contrast, in the case of the width of each of the gas passages C22a and C22b being less than 0.01 mm, forming such a small width is very difficult due to the limit of processing precision. With this structure, since plasma is hardly generated in each of the gas passages C22a and C22b, the O-rings 15, 17a, and 17b are desirably prevented from damages to be caused by an unintentional abnormal discharge.

A helium gas is supplied to the upper and lower gas passages C22a and C22b from the gas supply device 30 for a gas passage, through a gas introduction path C19 and gas blow-out holes C21 in the dielectric window 7. The gas blow-out holes C21 are disposed so as to communicate with the upper gas passage C22a. As shown in FIG. 1B, a large number of the gas blow-out holes C21 are disposed along the circumference of the peripheral edge of the round dielectric window 7, with predetermined intervals. The gas introduction path C19 is formed in the dielectric window 7 and connected so as to allow an end to communicate with all the gas blow-out holes C21. The other end of the gas introduction path C19 is connected to the gas supply device 30 for a gas passage.

Thus, helium is supplied to the upper and lower gas passages C22a and C22b in the following manner. By a fifth mass flow controller MFC5 installed in the gas supply device 30, helium is controlled to a predetermined flow rate. Moreover, the helium is directed to the upper gas flow passage C22a from the gas blow-out holes 21 through the gas introduction path C19. The helium directed into the upper gas passage C22 is allowed to pass through the inside of the upper gas flow passage C22a, that is, through a space between the outer surface of the upper cone-shaped cylinder portion 20a of the inner chamber 20 and the inner wall of the upper chamber 14, and supplied into the lower gas passage C22b in a space between the outer surface of the lower cylinder portion 20b of the inner chamber 20 and the inner wall of the lower chamber 16, after passing through the large number of through holes 20f disposed on the inner end side of the disc-shaped flange portion 20c in the intermediate portion of the inner chamber 20. Thereafter, the gas is allowed to pass through the lower gas passage C22b and enter the lower portion of the vacuum container 1 from the lower end of the lower gas passage C22b, and is then evacuated into the turbo molecular pump 3 from the exhaust port 11. Therefore, by setting the length of the gas passage including the upper gas passage C22a and the lower gas passage C22b to at least the mean free path or more, molecules of the helium gas discharged into the upper gas passage C22a from the gas blow-out holes C21 are forcibly made to proceed at least the mean free path or more, so that the molecules are guided to straightly proceed downward without being scattered by other molecules and the like; thus, it becomes possible to securely form a downward gas flow smoothly without disturbance in the upper gas passage C22a and lower gas passage C22b. In this manner, by allowing helium to flow from the upper gas passage C22a to the lower gas passage C22b, air that has invaded into the vacuum container 1 from the gap or the like between the coupling end portion 14b of the upper chamber 14 and the peripheral edge of the dielectric window 7 is allowed to flow from the upper gas passage C22a to the lower gas passage C22b together with helium, thereby making it possible to prevent the invaded air from flowing toward the substrate.

The following description will refer to processes for forming a layer of a source-drain extension region by the plasma doping method with use of the device shown in FIGS. 1A to 1C and FIG. 2.

The plasma doping conditions are, for example, set in the following manner: the material gas is AsH₃ (arsine) diluted with He (helium); the concentration of AsH₃ is set to 2.0% by mass in the material gas; the total flow rate of the material gas is 33 cm/min (standard state); the inner pressure of the vacuum container 1 is 0.35 Pa; the source power of the high-frequency power supply 5 for a coil (high-frequency power for generating plasma) is 500 W; the bias voltage (Vpp) of the high-frequency power supply 10 for a sample electrode is 250 V; the temperature of the substrate is 22° C.; and the plasma doping time is set to 60 seconds. Thus, AsH₃ diluted with helium, having a total flow rate of 33 cm/minute (standard state), is supplied into the vacuum chamber 1 from the gas blow-out holes A14 and B14. A temperature adjusting device, not shown, is disposed in the sample electrode 6 so as to heat or cool the substrate to maintain the same at a desired temperature.

Moreover, the fifth mass flow controller MCF5 in the gas supply device 30 for a gas passage is set so as to supply helium at 7.9 cm/minute (standard state) to the upper and lower gas passages C22a and C22b from the gas blow-out holes C21.

In this case, the flow rate of helium to be supplied from the gas blow-out holes C21 is desirably set to be equal to the total flow rate of the material gas or less, as well as to the amount of air invading into the vacuum container 1 or more. In the case when the flow rate of helium exceeds the total flow rate of the material gas, there is a possibility of adverse effects occurring in the processes. In the case when the flow rate of helium is less than the amount of air invading into the vacuum container 1, it is not possible to achieve desired effects. With this arrangement, it becomes possible to suppress the amount of mixed air into the plasma, while substantially no fluctuations are caused to the concentration of AsH₃ in the material gas, that is, the influences onto the amount of dose of As to be injected into the silicon substrate 9 are reduced to a minimum.

More desirably, the flow rate of helium to be supplied from the gas blow-out holes C21 is set to be equal to the total flow rate of the material gas or less, as well as to ten times or more of the amount of air invading into the vacuum container 1. Thus, the amount of mixed air into the plasma can be minimized.

Further desirably, the flow rate of helium to be supplied from the gas blow-out holes C21 is set to be equal to the total flow rate of the material gas or less, as well as to 100 times or more of the amount of air invading into the vacuum container 1. Thus, the mixture of air into the plasma can be positively avoided.

In a first working example in accordance with the first embodiment, the total amount of air that invades into the vacuum container 1 through the gap between the upper coupling end portion 14b of the upper chamber 14 and the peripheral edge of the dielectric window 7, through the gap between the lower coupling end portion 14c of the upper chamber 14 and the disc-shaped flange portion 20c of the inner chamber 20, through the gap between the disc-shaped flange portion 20c of the inner chamber 20 and the upper coupling end portion 16c of the lower chamber 16, or the like, is 0.079 m/minute (standard state), so that the flow rate of helium to be supplied from the gas blow-out holes C21 is set to 7.9 cm/minute (standard state), which is 100 times larger than the above value.

Thereafter, by supplying high-frequency power to the coil 8 from the high-frequency power supply 5 for a coil, plasma is generated in the vacuum container 1. At this time, the plasma is generated in a space covered with the surface of the silicon substrate 9, the inner wall of the inner chamber 20, and the lower surface of the top plate 7. However, since there is no sufficient space inside the upper and lower gas passages C22a and C22b to maintain the plasma, no plasma is generated therein so that the inside of the upper and lower gas passages C22a and C22b is brought into a state in which only helium is flowing downward from above.

By using this structure, a minute amount of air that invades into the vacuum container 1 through the gap between the upper coupling end portion 14b of the upper chamber 14 and the peripheral edge of the dielectric window 7 in spite of the suppression by the O-ring 15 is caused to flow by a large amount of helium that is flowing through the upper gas passage C22a and the lower gas passage C22b. As a result, most of the minute amount of air that invades into the vacuum container 1 is evacuated toward the turbo molecular pump 3 through the exhaust port 11, without reaching a processing space in which the silicon substrate 9 is processed by the generated plasma. Therefore, without allowing air to be formed into plasma, the amount of the air component mixed into the silicon substrate 9 can be suppressed to a low level.

Next, by using the device as shown in FIGS. 1A to 1C and FIG. 2, a layer of a source-drain extension region was formed by the above-mentioned plasma doping method, the results of which are described.

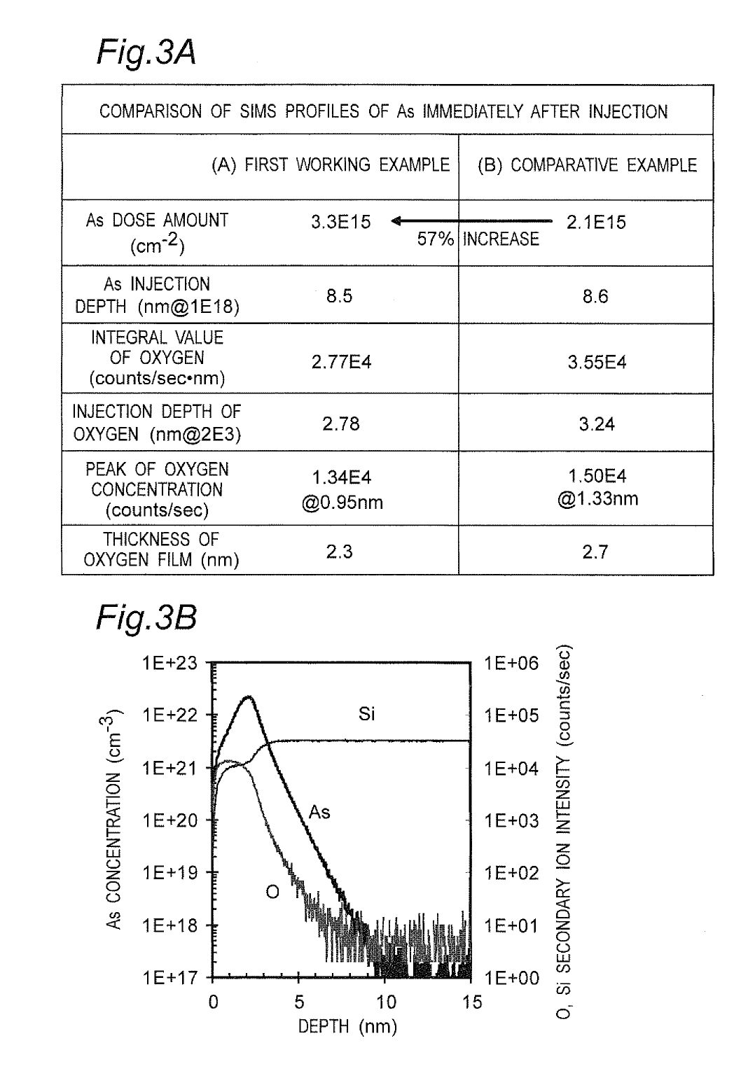

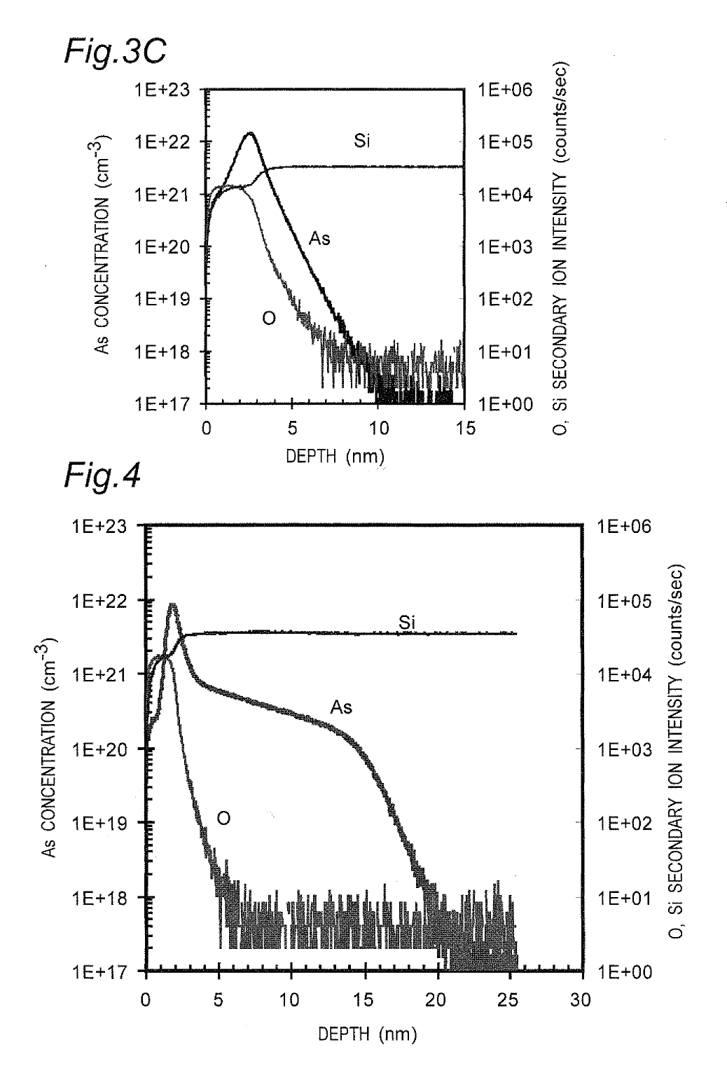

Two graphs in FIGS. 3B and 3C out of FIGS. 3A to 3C each illustrate the SIMS profile of As on the surface area of the silicon substrate 9 immediately after the injection. As shown in FIGS. 3A to 3C, in the first working example described above in accordance with the first embodiment, the thickness of the oxide film was 2.3 nm, while that of the comparative example was 2.7 nm, with the result that the oxide film in the first working example was thinner than that of the comparative example by 0.4 nm. In contrast to the fact that the oxide film was made thinner, the amount of dose of As was 2.1 E15 cm⁻² in the comparative example in comparison with 3.3 E15 cm⁻² in the first working example, so that the film thickness of the first working example was larger than that of the comparative example by 57%. The profile of the first working example implies that, in a manner so as to replace oxygen corresponding to the oxide film portion being reduced by 0.4 nm, As having an amount as much as 1.2 E15 cm⁻² is introduced into the corresponding portion. In this case, the thickness of the oxide film is defined by a depth that makes the secondary ion intensity of oxygen is ½ of the peak intensity.

FIG. 4 illustrates the SIMS profile of As after the annealing process. A region from the surface down to about 15 nm has a high concentration of arsenic that exceeds 1 E20 cm⁻² and the arsenic concentration in the region has a higher value than that of the n-layer formed by ion injection, so as to greatly help a reduction of the sheet resistance. Moreover, the thickness of the oxide film on the outermost surface is thinner than that formed by the plasma doping method using a conventional plasma processing apparatus.

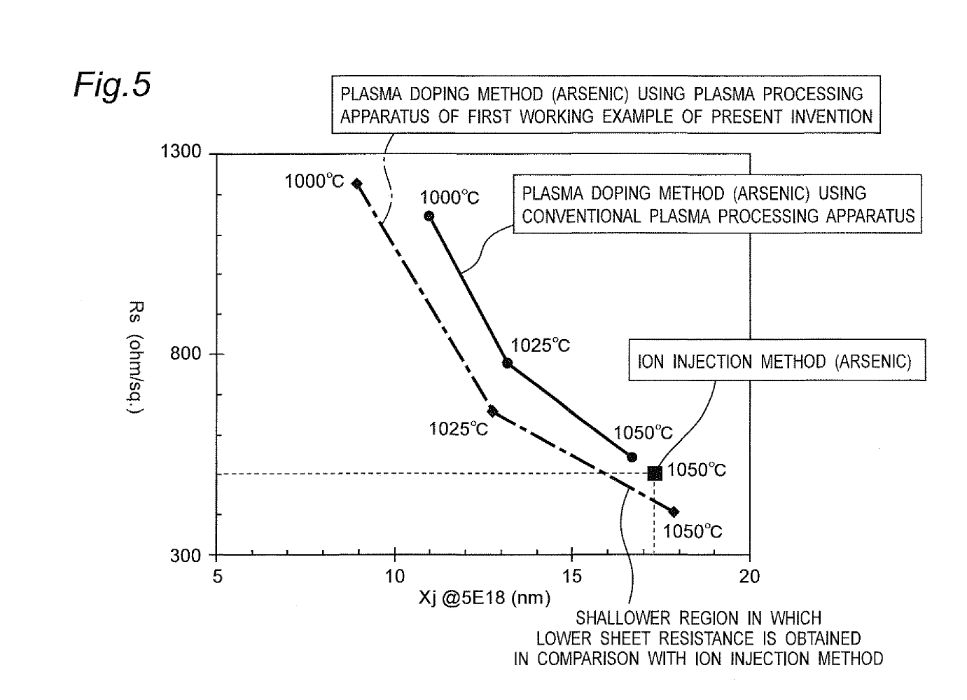

FIG. 5 is a graph showing the comparisons of Xj-Rs characteristics obtained by evaluation of diffusion depths (Xj)) and sheet resistances (Rs) of two n-layers that are respectively formed on the surfaces of the silicon substrates 9 by using the plasma doping apparatus of the first working example and the plasma doping apparatus of the comparative example (which is provided with none of the gas passages C22a and C22b, the gas blow-out holes C21, and the gas supplying device 30 for a gas passage) under the same plasma doping conditions. In this case, the plasma doping conditions are, for example, set in the following manner: the material gas is AsH₃ (arsine) diluted with He (helium); the concentration of AsH₃ is set to 2.0% by mass in the material gas; the total flow rate of the material gas is 33 cm/min (standard state); the inner pressure of the vacuum container 1 is 0.35 Pa; the source power of the high-frequency power supply 5 for a coil (high-frequency power for generating plasma) is 500 W; the bias voltage (Vpp) of the high-frequency power supply 10 for a sample electrode is 250 V; the temperature of the substrate is 22° C.; and the plasma doping time is set to 60 seconds. Thus, AsH₃ diluted with helium, having a total flow rate of 33 cm/minute (standard state), was supplied into the vacuum chamber 1 from the gas blow-out holes A12 and B12. Upon the comparisons of the Xj-Rs characteristics of the two layers with the equal Xj, the first working example has the sheet resistance that is lower than that of the comparative example by as much as 15 to 20%. Therefore, the first working example makes it possible to produce a semiconductor device having a larger on-state current in comparison with the comparative example.

In accordance with the first embodiment, there is provided the inner chamber 20, which is disposed further inside the upper chamber 14 and the lower chamber 16 so as to be close to these two chambers 14 and 16. Moreover, in the first embodiment, the upper and lower gas passages C22a and C22b each serving as one example of the dilution gas path are formed between the inner chamber 20 and a chamber such as the two chambers 14 and 16, and the gas supply device 30 is provided for use in supplying a gas to the gas passages C22a and C22b. With this structure, by allowing helium to flow from the upper end of the upper gas passage C22a toward the lower end of the lower gas passage C22b, air that has invaded into the vacuum container 1 through the gap between the coupling end portion 14b of the upper chamber 14 and the peripheral edge of the dielectric window 7, the gap between the lower coupling end portion 14c of the upper chamber 14 and the disc-shaped flange portion 20c of the inner chamber 20, or the upper coupling end portion 16c of the lower chamber 16 and the disc-shaped flange portion 20c of the inner chamber 20, is allowed to flow from the upper gas passage C22a toward the lower gas passage C22b together with helium, so that the invaded air can be prevented from flowing toward the substrate. In other words, the air that has invaded into the vacuum container 1 through any one of the gaps can be directed toward the exhaust port 11 through the upper gas passage C22a or the lower gas passage C22b, which is separated from the processing space inside the vacuum container 1 so as not to directly exert adverse effects to the plasma processing of the substrate 9. Therefore, by preventing leaking air from invading toward the substrate in the vacuum container 1, it is possible to suppress doping of the substrate 9 with oxygen derived from the leaking air. As a result, since the oxide film on the surface of the substrate 9 is made thinner and the As concentration of the surface is made higher, so that superior effects, that is, improvement of the Xj-Rs characteristics, can be obtained, thereby making it possible to provide a plasma doping apparatus capable of producing a semiconductor device having a large on-state current.

### Second Embodiment

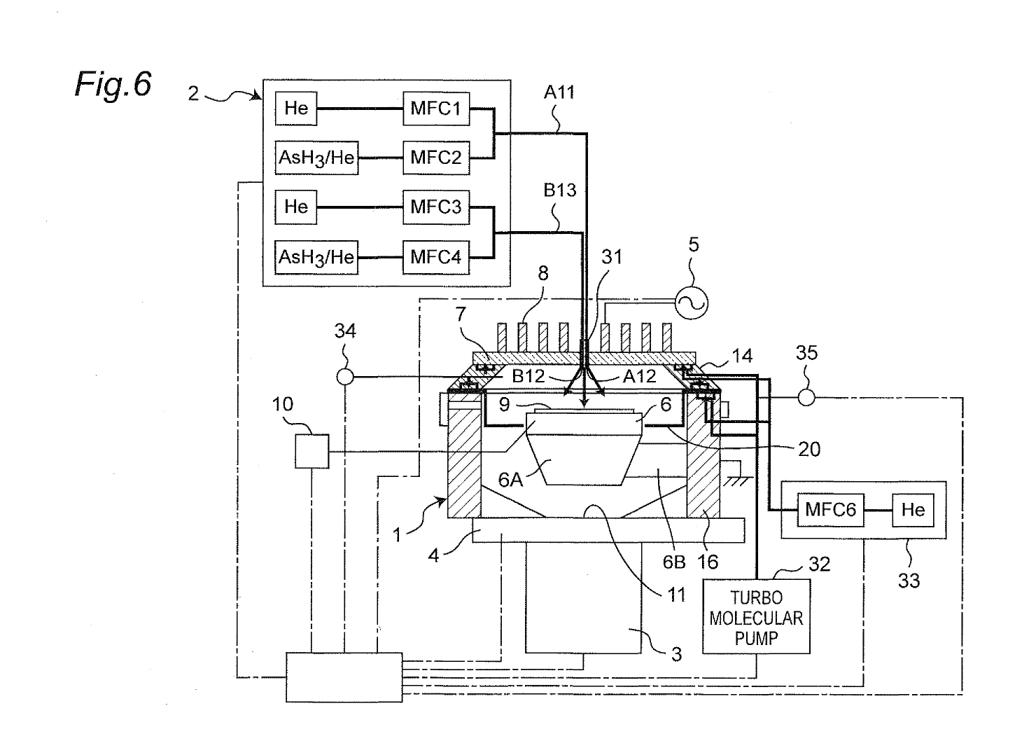

Referring to FIGS. 6 to 8, the following description will refer to a second embodiment of the present invention.

FIG. 6 is a partial cross-sectional view showing a plasma doping apparatus for use in the second embodiment of the present invention. The bottom view of a top plate 7 of the plasma doping apparatus of the second embodiment is the same as FIG. 1B of the first embodiment, and the plan view of an inner chamber 20 is also the same as FIG. 1C of the first embodiment.

In FIGS. 6, 1B, and 1C, while a predetermined gas is being introduced from a gas supply device 2 into a vacuum container 1 that is provided with the top plate 7 on an upper opening in an upper end surface and is grounded, evacuation is performed by a turbo molecular pump 3 serving as one example of a gas evacuation device, and the inside of the vacuum container 1 can be maintained at a predetermined pressure by a pressure adjusting valve 4. A high-frequency power supply 5 for a coil supplies a coil 8 that serves as one example of an upper electrode and is formed near a dielectric window (dielectric window member) 7 serving as one example of the top plate so as to face a sample electrode 6, with high frequency power of 13.56 MHz, so that plasma can be generated in the vacuum container 1. A silicon substrate 9 as a sample is placed on the sample electrode 6. There is provided a high-frequency power supply 10 for a sample electrode used for supplying high frequency power to the sample electrode 6. This high-frequency power supply 10 for a sample electrode functions as a voltage source that controls the electric potential of the sample electrode 6 so as to allow the substrate 9 serving as the sample to maintain a negative electric potential relative to the plasma.

In this manner, ions in the plasma are accelerated toward the surface of the sample to collide therewith so that impurities can be introduced into the surface of the substrate 9 as the sample.

In this case, the gas supplied from the gas supply device 2 is evacuated into the pump 3 through an exhaust port 11. The turbo molecular pump 3 and the exhaust port 11 are disposed right below the sample electrode 6. The sample electrode 6 is a seat having a substantially round shape on which the substrate 9 is placed. The sample electrode 6 is supported by an insulating support base 6A, and the support base 6A is secured onto an inner wall of the vacuum container 1 by a support member 6B so as to be disposed in the center in the vacuum container 1.

A gas is supplied from the gas supply device 2 into a gas introduction path All that connects the gas supply device 2 to the inside of the vacuum container 1 in the following manner. The flow rate of a gas containing an impurity material gas is controlled to a predetermined value by first and second flow-rate control devices (mass flow controllers) MFC1 and MFC2 that are installed in the gas supply device 2. In general, a gas prepared by diluting the impurity material gas with helium, such as arsine (AsH₃) that is diluted to 2% with helium (He), is used as the impurity material gas, the flow rate of which is controlled by the second mass flow controller MFC2. Moreover, the flow rate of helium is controlled by the first mass flow controller MFC1, and the gases (helium and the impurity material gas) of which flow rates have been controlled by the first and second mass flow controllers MFC1 and MFC2 are mixed with each other in the gas supply device 2, and the mixed gas is then introduced into the vacuum container 1 from a gas blow-out hole A12 of a gas injector 31, which is secured to the dielectric window 7 in a manner so as to pass through a through hole 7a in the center of the dielectric window 7, through the gas introduction path A11, and further through the gas injector 31. The gas blow-out hole A12 is designed to blow the gas toward the center of the substrate 9 from the surface opposed to the substrate 9.

In the same manner, into a gas introduction path B13 that connects the gas supply device 2 with the vacuum container 1, a gas is supplied from the gas supply device 2 in the following manner. The flow rate of a gas containing an impurity material gas is controlled to a predetermined value by third and fourth flow-rate control devices (mass flow controllers) MFC3 and MFC4 that are installed in the gas supply device 2. In general, a gas prepared by diluting the impurity material gas with helium, such as arsine (AsH₃) that is diluted to 2% with helium (He), is used as the impurity material gas, the flow rate of which is controlled by the fourth mass flow controller MFC4. Moreover, the flow rate of helium is controlled by the third mass flow controller MFC3, and the gases (helium and the impurity material gas) of which flow rates have been controlled by the third and fourth mass flow controllers MFC3 and MFC4 are mixed with each other in the gas supply device 2, and the mixed gas is then introduced into the vacuum container 1 from a gas blow-out hole B12 of the gas injector 31, which is secured to the dielectric window 7 in a manner so as to penetrate the center of the dielectric window 7, through the gas introduction path B13, and further through the gas injector 31. The gas blow-out hole B12 is designed to blow the gas toward the peripheral edge of the substrate 9 from the surface opposed to the substrate 9.

Moreover, a control device 1000, which is connected to the gas supply device 2, the pump 3, the pressure adjusting valve 4, the high-frequency power supply 5 for a coil, and the high-frequency power supply 10 for a sample electrode, is provided so that the operations of the gas supply device 2, the pump 3, the pressure adjusting valve 4, the high-frequency power supply 5 for a coil, and the high-frequency power supply 10 for a sample electrode are respectively controlled by the control device 1000.

One of the features of the second embodiment of the present invention is that at a connecting portion between the top plate 7 and the vacuum container 1, inside an O-ring 21 serving as one example of a sealing member on the outer side of the upper end for tightly sealing a gap between a coupling end portion 14b of the vacuum container 1 and the peripheral edge of the top plate 7, which are opposed to each other, there is provided a suction groove 14j on the outer side of the upper end or a suction groove 14m on the inner side of the upper end, each of which is arranged along the entire circumference of the end surface of the coupling end portion 14b of the vacuum container 1, Further, there is provided at least a regulating gas suction device 32 serving as one example of a suction groove evacuation device that is connected to the upper-end outer side suction groove 14j or the upper-end inner side suction groove 14m, and sucks a gas inside the upper-end outer side suction groove 14j or the upper-end inner side suction groove 14m so that the pressure inside the upper-end outer side suction groove 14j or the upper-end inner side suction groove 14m is made smaller than the pressure inside the vacuum container 1. With this structure, air that invades into the vacuum chamber 1 from the outside of the vacuum container 1 through the gap between the coupling end portion 14b of the vacuum chamber 1 and the peripheral edge of the top plate 7 is prevented from flowing toward the substrate 9.

The regulating gas suction device 32 is also connected to the control device 1000 so that the operation of the regulating gas suction device 32 is controlled by the control device 1000. A turbo molecular pump may be used as one example of the regulating gas suction device 32. As one example, in FIG. 6, the vacuum chamber 1 is constituted by an upper chamber 14 having the top plate 7 on an upper end and a lower chamber 16 located below the upper chamber 14, and is further provided with an inner chamber 20 that is disposed further inside of the upper chamber 14 and the lower chamber 16 so as to be close to these two chambers 14 and 16. The present invention is not intended to be limited to this structure, and the upper chamber 14 and the lower chamber 16 maybe integrally formed, or in contrast, the vacuum container 1 may be divided into 3 or more chambers.

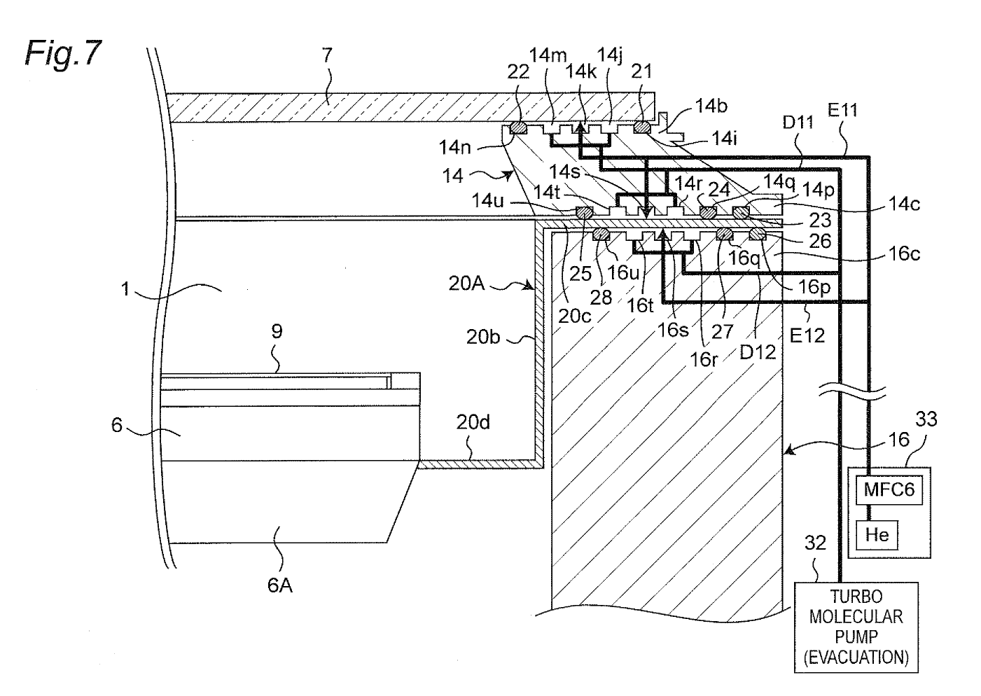

FIG. 7 is a partially enlarged cross-sectional view showing the upper-end outer side suction groove 14j or the upper-end inner side suction groove 14m at the coupling end portion 14b of the upper chamber 14 of the vacuum container 1, the regulating gas suction device 32, and the like in the plasma doping apparatus for use in the second embodiment of the present invention. FIG. 8 is a plan view showing the lower chamber 16 in which the respective grooves are concentrically formed independently. In the upper coupling end portion 14b and lower coupling end portion 14c of the upper chamber 14, the respective grooves are concentrically formed independently in the same manner.

In FIG. 2, the upper chamber 14 is installed so that the peripheral edge of the dielectric window 7 is supported by the end surface of its upper coupling end portion 14b.

The amount of air that invades into the vacuum container 1 from the outside of the vacuum container 1 through the gap between the upper chamber 14 and the dielectric window 7 is reduced by a structure in which the peripheral edge of the dielectric window 7 and the coupling end portion 14b of the upper chamber 14 are tightly joined and sealed with the vacuum-sealing O-ring 21 disposed in an outermost third concave groove 14i that is formed into a circular ring shape and a vacuum-sealing O-ring 22 serving as a sealing member and disposed in an innermost fourth concave groove 14n that is formed into a circular ring shape, being interposed therebetween on the end surface of the coupling end portion 14b of the upper chamber 14.

Moreover, in the end surface of the coupling end portion 14b of the upper chamber 14, the upper-end outer side suction groove 14j, a first dilution gas flow groove 14k, and the upper-end inner side suction groove 14m are independently formed into a circular ring shape between the outermost third concave groove 14i and the innermost fourth concave groove 14n from the outside toward the inside. A gas supply device 33 for dilution gas flow grooves, which serves as one example of a dilution gas supply device, is connected to the first dilution gas flow groove 14k through a supply pipe E11, so that a dilution gas, for example, helium, to be supplied into the first dilution gas flow groove 14k is controlled to a predetermined flow rate by a sixth mass flow controller MFC6 installed in the gas supply device 33 for dilution gas flow grooves. On the other hand, as described earlier, the regulating gas suction device 32 is connected to the upper-end outer side suction groove 14j and the upper-end inner side suction groove 14m through a suction pipe D11, and the gases inside the upper-end outer side suction groove 14j and the upper-end inner side suction groove 14m are respectively sucked by the regulating gas suction device 32 so that pressures inside the upper-end outer side suction groove 14j and the upper-end inner side suction groove 14m are respectively made lower than the pressure inside the vacuum container 1. The regulating gas suction device 32 is also connected to the control device 1000 so that the operation of the regulating gas suction device 32 is controlled by the control device 1000.

Moreover, a disc-shaped flange portion 20c that protrudes outward from the intermediate portion of the inner chamber 20 is sandwiched between the lower coupling end portion 14c of the upper chamber 14 and the upper coupling end portion 16c of the lower chamber 16 and is tightened to be secured, so that the inner chamber 20 is secured by the upper chamber 14 and the lower chamber 16.

The amount of air that invades into the vacuum container 1 from the outside of the vacuum container 1 through the gap between the lower coupling end portion 14c of the upper chamber 14 and the disc-shaped flange portion 20c of the inner chamber 20 is reduced by a structure in which the lower coupling end portion 14c of the upper chamber 14 and the disc-shaped flange portion 20c of the inner chamber 20 are tightly joined and sealed with a vacuum-sealing O-ring 24 serving as one example of a sealing member and disposed in a fifth concave groove 14q that is formed outside into a circular ring shape and a vacuum-sealing O-ring 25 serving as one example of a sealing member and disposed in an innermost sixth concave groove 14u in a circular ring shape, being interposed therebetween on the end surface of the lower coupling end portion 14c of the upper chamber 14.

Moreover, on the end surface of the lower coupling end portion 14c of the upper chamber 14, a lower-end outer side suction groove 14r, a second dilution gas flow groove 14s, and a lower-end inner side suction groove 14t are independently formed into a circular ring shape between the outer fifth concave groove 14q and the innermost sixth concave groove 14u from the outside toward the inside. The gas supply device 33 for dilution gas flow grooves is connected to the second dilution gas flow groove 14s through the supply pipe E11 so that a dilution gas, for example, helium, to be supplied into the second dilution gas flow groove 14s, is controlled to a predetermined flow rate by the sixth mass flow controller MFC6 provided in the gas supply device 33 for dilution gas flow grooves, in the same manner as in the first dilution gas flow groove 14k. On the other hand, similarly to the above, the regulating gas suction device 32 is connected to the lower-end outer side suction groove 14r and the lower-end inner side suction groove 14t through the suction pipe D11, and the gases inside the lower-end outer side suction groove 14r and the lower-end inner side suction groove 14t are respectively sucked by the regulating gas suction device 32 so that pressures inside the lower-end outer side suction groove 14r and the lower-end inner side suction groove 14t are respectively made lower than the pressure inside the vacuum container 1.

Moreover, the lower coupling end portion 14c of the conductive upper chamber 14 and the disc-shaped flange portion 20c of the conductive inner chamber 20 are made electrically conductive to each other by a conductive metal coil 23 for use in grounding, which is disposed inside a circular ring-shaped seventh concave groove 14p placed outside the fifth concave groove 14q in the end surface of the lower coupling end portion 14c of the upper chamber 14.

The amount of air that invades into the vacuum container 1 from the outside of the vacuum container 1 through the gap between the disc-shaped flange portion 20c of the inner chamber 20 and the upper coupling end portion 16c of the lower chamber 16 is reduced by a structure in which the upper coupling end portion 16c of the lower chamber 16 and the disc-shaped flange portion 20c of the inner chamber 20 are tightly joined and sealed with a vacuum-sealing O-ring 27 serving as one example of a sealing member and disposed in the outer fifth concave groove 16q that is formed into a circular ring shape and a vacuum-sealing O-ring 28 serving as one example of a sealing member disposed in an innermost sixth concave groove 16u that is formed into a circular ring shape, being interposed therebetween on the end surface of the upper coupling end portion 16c of the lower chamber 16.

Moreover, on the end surface of the upper coupling end portion 16c of the lower chamber 16, an upper-end outer side suction groove 16r, a third dilution gas flow groove 16s, and an upper-end inner side suction groove 16t are independently formed into a circular ring shape between the outer fifth concave groove 16q and the innermost sixth concave groove 16u from the outside toward the inside. The gas supply device 33 for dilution gas flow grooves is connected to the third dilution gas flow groove 16s through a supply pipe E12 so that a dilution gas, for example, helium, to be supplied into the third dilution gas flow groove 16s, is controlled to a predetermined flow rate by the sixth mass flow controller MFC6 provided in the gas supply device 33 for dilution gas flow grooves, in the same manner as in the first dilution gas flow groove 14k and the second dilution gas flow groove 14s. On the other hand, similarly to the above, the regulating gas suction device 32 is connected to the upper-end outer side suction groove 16r and the upper-end inner side suction groove 16t through a suction pipe D12, and the gases inside the upper-end outer side suction groove 16r and the upper-end inner side suction groove 16t are respectively sucked by the regulating gas suction device 32 so that pressures inside the upper-end outer side suction groove 16r and the upper-end inner side suction groove 16t are respectively made lower than the pressure inside the vacuum container 1.

The disc-shaped flange portion 20c of the conductive inner chamber 20 and the upper coupling end portion 16c of the conductive lower chamber 16 are made electrically conductive to each other by a conductive metal coil 26 for use in grounding, disposed inside a circular ring-shaped seventh concave groove 16p placed outside the fifth concave groove 16q on the end surface of the upper coupling end portion 16c of the lower chamber 16.

Furthermore, a vacuum-container inner pressure measuring device 34 for measuring the inner pressure of the vacuum container 1 is provided in the vacuum container 1, and a suction-groove inner pressure measuring device 35 is connected to the upper-end outer side suction groove 14j, the upper-end inner side suction groove 14m, the lower-end outer side suction groove 14r, the lower-end inner side suction groove 14t, the upper-end outer side suction groove 16r, and the upper-end inner side suction groove 16t, or to the suction pipes D11 and D12 that communicate with the suction grooves, so that the inner pressure of each of the suction grooves or the inner pressure of each of the suction pipes D11 and D12 can be measured.

Measured values of the respective vacuum-container inner pressure measuring device 34 and suction-groove inner pressure measuring device 35 are respectively inputted to the control device 1000, and based upon the measured values, the control device 1000 respectively controls the operations of the pump 3 and the regulating gas suction device 32 so that the pressure in each of the suction grooves is made lower than the inner pressure of the vacuum container 1.

With this structure, on the lower end surface of the peripheral edge of the dielectric window 7 or the end surface of the coupling end portion 14b of the upper chamber 14, on the end surface of the lower coupling end portion 14c of the upper chamber 14 or the upper end surface of the disc-shaped flange portion 20c of the inner chamber 20, or on the lower end surface of the disc-shaped flange portion 20c of the inner chamber 20 or the end surface of the upper coupling end portion 16c of the lower chamber 16, there are respectively formed an outward gas flow that flows from the inside of the vacuum chamber 1 outward along the end surface from the first dilution gas flow groove 14k (or one of the second dilution gas flow groove 14s and the third dilution gas flow groove 16s) to the upper-end outer side suction groove 14j (or one of the lower-end outer side suction groove 14r and the upper-end outer side suction groove 16r), and an inward gas flow that flows from the outside of the vacuum chamber 1 inward along the end surface from the first dilution gas flow groove 14k (or one of the second dilution gas flow groove 14s and the third dilution gas flow groove 16s) to the upper-end inner side suction groove 14m (or one of the lower-end inner side suction groove 14t and the upper-end inner side suction groove 16t).

The air that tries to invade into the vacuum container 1 from the outside of the vacuum container 1 through the gap between the lower end surface of the peripheral edge of the dielectric window 7 and the end surface of the coupling end portion 14b of the upper chamber 14, the gap between the end surface of the lower coupling end portion 14c of the upper chamber 14 and the upper end surface of the disc-shaped flange portion 20c of the inner chamber 20, or the gap between the lower end surface of the disc-shaped flange portion 20c of the inner chamber 20 and the end surface of the upper coupling end portion 16c of the lower chamber 16, is sucked into the upper-end outer side suction groove 14j (or one of the lower-end outer side suction groove 14r and the upper-end outer side suction groove 16r). Therefore, it is possible to prevent the air from further proceeding into the vacuum container 1 beyond the upper-end outer side suction groove 14j (or one of the lower-end outer side suction groove 14r and the upper-end outer side suction groove 16r).

Even if the air from outside the vacuum container 1 should proceed into the vacuum container 1 beyond the upper-end outer side suction groove 14j (or one of the lower-end outer side suction groove 14r and the upper-end outer side suction groove 16r), this air is sucked into the upper-end inner side suction groove 14m (or one of the lower-end inner side suction groove 14t and the upper-end inner side suction groove 16t) by the inward gas flow flowing from the first dilution gas flow groove 14k (or one of the second dilution gas flow groove 14s and the third dilution gas flow groove 16s) to the upper-end inner side suction groove 14m (or one of the lower-end inner side suction groove 14t and the upper-end inner side suction groove 16t).

Therefore, the air that tries to invade into the vacuum container 1 from the outside of the vacuum container 1 is sucked into the upper-end outer side suction groove 14j (or one of the lower-end outer side suction groove 14r and the upper-end outer side suction groove 16r) or the upper-end inner side suction groove 14m (or one of the lower-end inner side suction groove 14t and the upper-end inner side suction groove 16t), so that the air is prevented from proceeding into the vacuum container 1.

In the second embodiment, the pressure inside the vacuum container 1, that is, the pressure of the processing space in the vacuum container 1, is preferably set to, for example, 0.01 Pa to 10 Pa, and more preferably, to 0.1 Pa to 10 Pa. In the case when the pressure in the processing space is less than 0.01 Pa, the amount of the material gas is too small to cause an extreme reduction in ion density, with the result that the injection itself of impurity ions becomes difficult. In contrast, when the pressure in the processing space exceeds 10 Pa, the amount of a scraped injection subject such as silicon is too large thereby to cause an issue of deformation of the injection subject.

The pressure range in which the inside of each of the suction grooves is vacuumized by the regulating gas suction device 32 is desirably set to a level or less of the pressure to be used in the processing space in the vacuum container 1. With this arrangement, although the gas inside the processing space may be drawn from the processing space toward the inside of each of the suction grooves that are vacuumized by the regulating gas suction device 32, the atmosphere, that is, air, is prevented from invading into the processing space from the outside of the vacuum container 1. However, in the case when the pressure inside each of the suction grooves to be vacuumized by the regulating gas suction device 32 is reduced by five digits smaller than the pressure to be used in the processing space, an issue is raised that the amount of gas to be drawn from the processing space toward the inside of each of the suction grooves to be vacuumized by the regulating gas suction device 32 becomes larger. The pressure inside each of the suction grooves to be vacuumized by the regulating gas suction device 32 can be nonproblematically reduced by three digits smaller than the pressure to be used in the processing space; however, from the economic viewpoint, the pressure inside each of the suction grooves to be vacuumized by the regulating gas suction device 32 is most desirably reduced by about one digit smaller than the pressure to be used in the processing space. By making even a small difference in pressures between the inside of each of the suction grooves and the inside of the processing space, it is possible to obtain such an effect as to prevent air from invading toward the processing space from the outside of the vacuum container 1; therefore, the pressure difference is most desirably set within a range of one digit.

In the second embodiment, the plasma doping conditions are, for example, set in the following manner: the material gas is AsH₃ (arsine) diluted with He (helium); the concentration of AsH₃ is set to 2.0% by mass in the material gas; the total flow rate of the material gas is 33 cm/min (standard state); the inner pressure of the vacuum container 1 is 0.35 Pa; the source power of the high-frequency power supply 5 for a coil (high-frequency power for generating plasma) is 500 W; the bias voltage (Vpp) of the high-frequency power supply 10 for a sample electrode is 250 V; the temperature of the substrate is 22° C.; and the plasma doping time is set to 60 seconds. Thus, AsH₃diluted with helium, having a total flow rate of 33 cm/minute (standard state), is supplied into the vacuum container 1 from the gas blow-out hole of the gas injector. It is noted that a temperature adjusting device, not shown, is disposed in the sample electrode 6 to heat or cool the substrate so as to maintain the substrate at a desired temperature.

Moreover, the pressure inside each of the suction grooves to be vacuumized by the regulating gas suction device 32 is set to 0.1 Pa.

In accordance with the second embodiment, at the coupling portion between the peripheral edge of the dielectric window 7 and the coupling end portion 14b of the upper chamber 14, at the coupling portion between the lower coupling end portion 14c of the upper chamber 14 and the disc-shaped flange portion 20c of the inner chamber 20, or at the coupling portion between the disc-shaped flange portion 20c of the inner chamber 20 and the upper coupling end portion 16c of the lower chamber 16, there are respectively formed an outward gas flow that flows from the inside of the vacuum container 1 outward along the end surface from the dilution gas flow groove 14k, 14s, or 16s to the outer side suction groove 14j, 14r, or 16r, and an inward gas flow that flows from the outside of the vacuum container 1 inward along the end surface from the dilution gas flow groove 14k, 14s, or 16s to the inner side suction groove 14m, 14t, or 16t. Moreover, the air that tries to invade into the vacuum container 1 from the outside of the vacuum container 1 through the gap between the peripheral edge of the dielectric window 7 and the coupling end portion 14b of the upper chamber 14, the gap between the lower coupling end portion 14c of the upper chamber 14 and the disc-shaped flange portion 20c of the inner chamber 20, or the gap between the disc-shaped flange portion 20c of the inner chamber 20 and the upper coupling end portion 16c of the lower chamber 16, is sucked into the outer side suction groove 14j, 14r, or 16r; therefore, the air is prevented from further proceeding into the vacuum container 1 beyond the upper-end outer side suction grooves 14j, 14r, and 16r. Even if the air outside the vacuum container 1 should proceed into the vacuum container 1 beyond the outer side suction groove 14j, 14r, or 16r, this air is sucked into the inner side suction groove 14m, 14t, or 16t by the inward gas flow flowing from the dilution gas flow groove 14k, 14s, or 16s to the inner side suction groove 14m, 14t, or 16t. Therefore, the air that tries to invade into the vacuum container 1 from the outside of the vacuum container 1 is sucked into the outer side suction groove 14j, 14r, or 16r or the inner side suction groove 14m, 14t, or 16t, so that the air is prevented from invading into the vacuum container 1. As a result, it is possible to suppress the amount of the air that is leaked into the vacuum container 1 from the outside thereof and mixed into the plasma.

It is noted that the present invention is not intended to be limited to the above-mentioned embodiments, and may be carried out in various other modes.

In the second embodiment, at the respective coupling portions, it is not necessarily required to provide the three types of grooves, namely, the outer side suction grooves 14j, 14r, and 16r, the dilution gas flow grooves 14k, 14s, and 16s, and the inner side suction grooves 14m, 14t, and 16t.

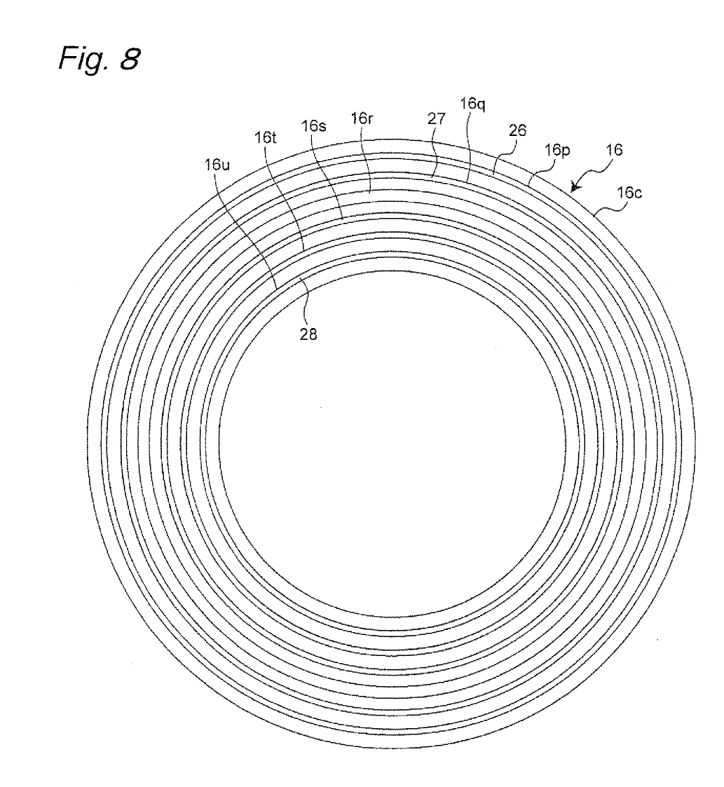

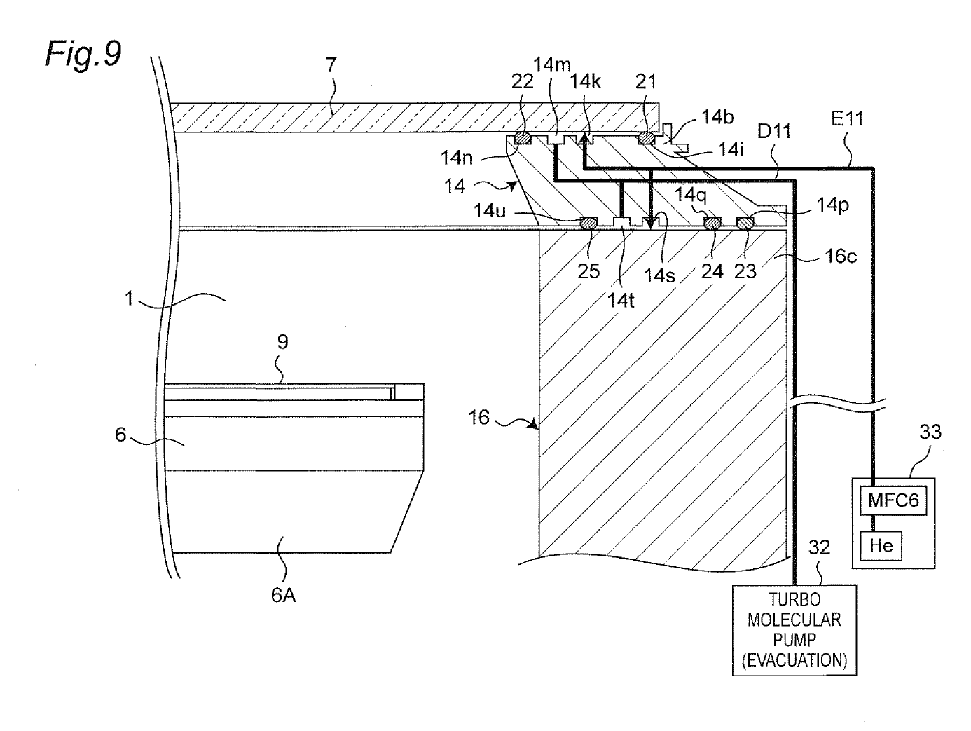

For example, as shown in FIG. 9, another structure maybe provided in which, by not forming the outer side suction grooves 14j, 14r, and 16r, there is formed only the inward gas flow flowing from the outside of the vacuum container 1 inward along the end surface of the coupling end portion 14b from the dilution gas flow groove 14k, 14s, or 16s toward the inner side suction groove 14m, 14t, or 16t, so that the air trying to invade into the vacuum container 1 from the outside of the vacuum container 1 is sucked into the inner side suction groove 14m, 14t, or 16t and cannot invade into the vacuum container 1.

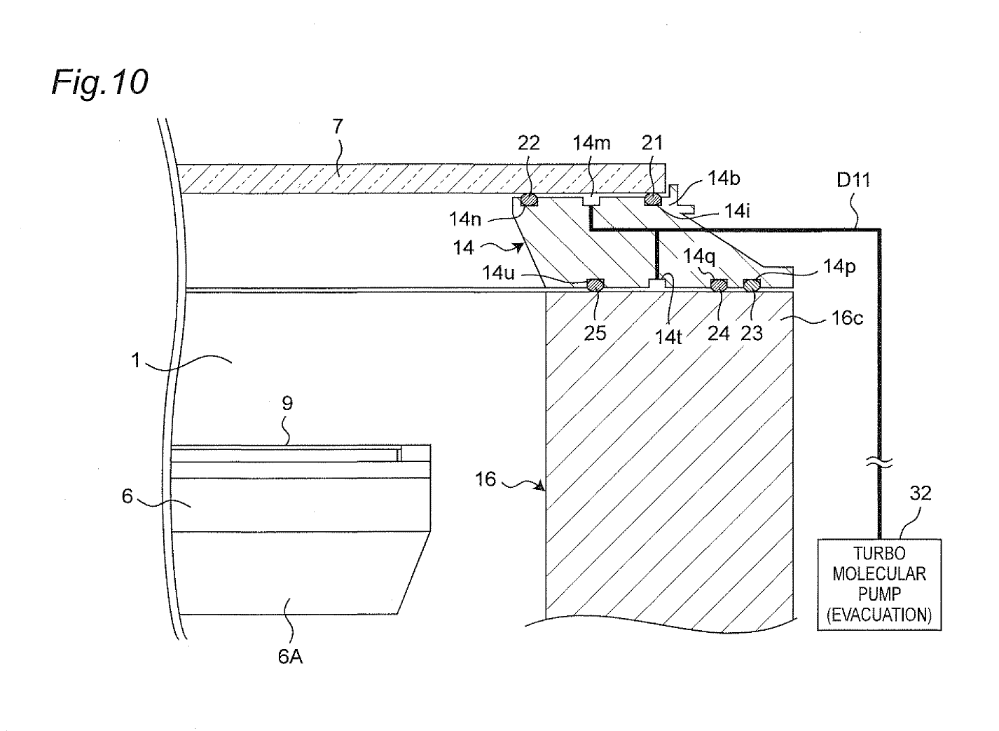

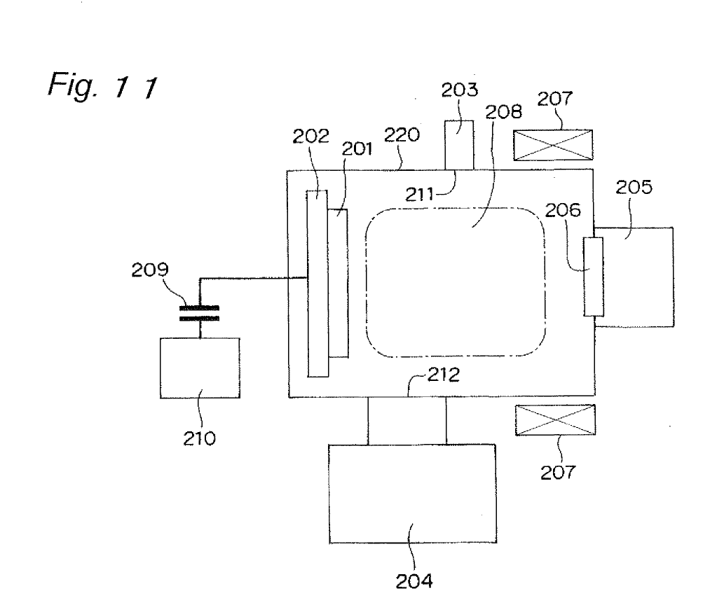

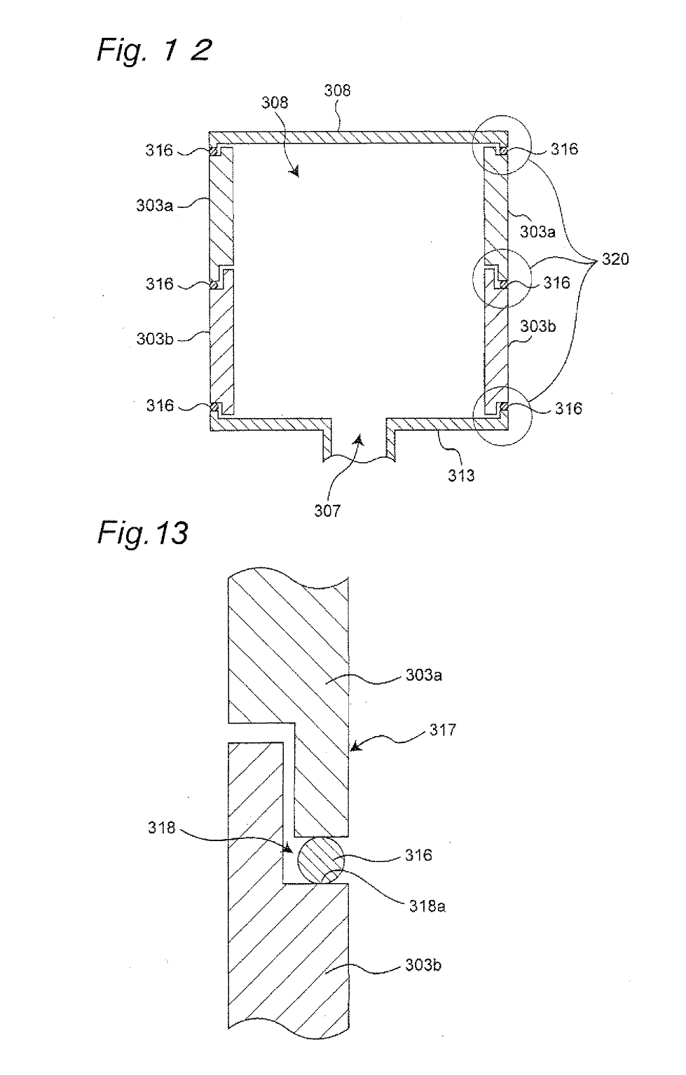

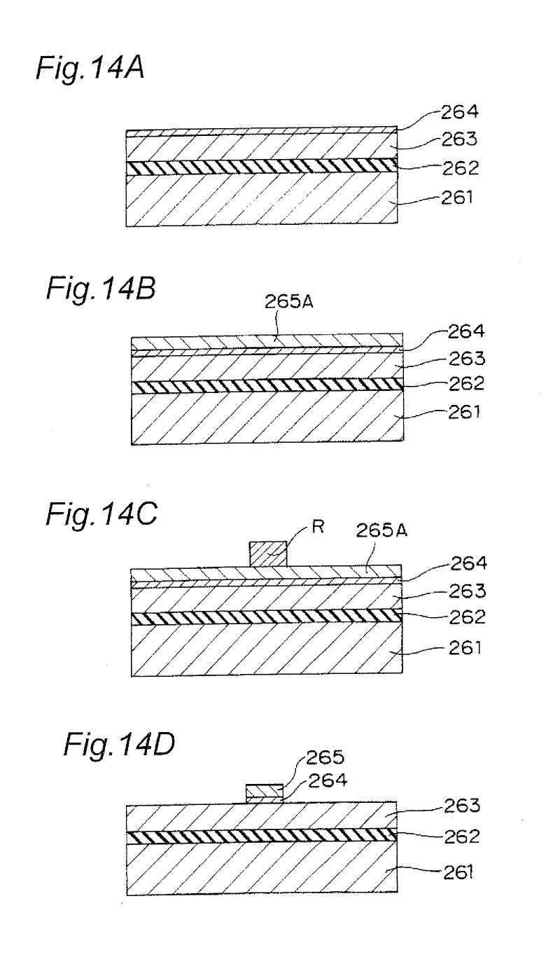

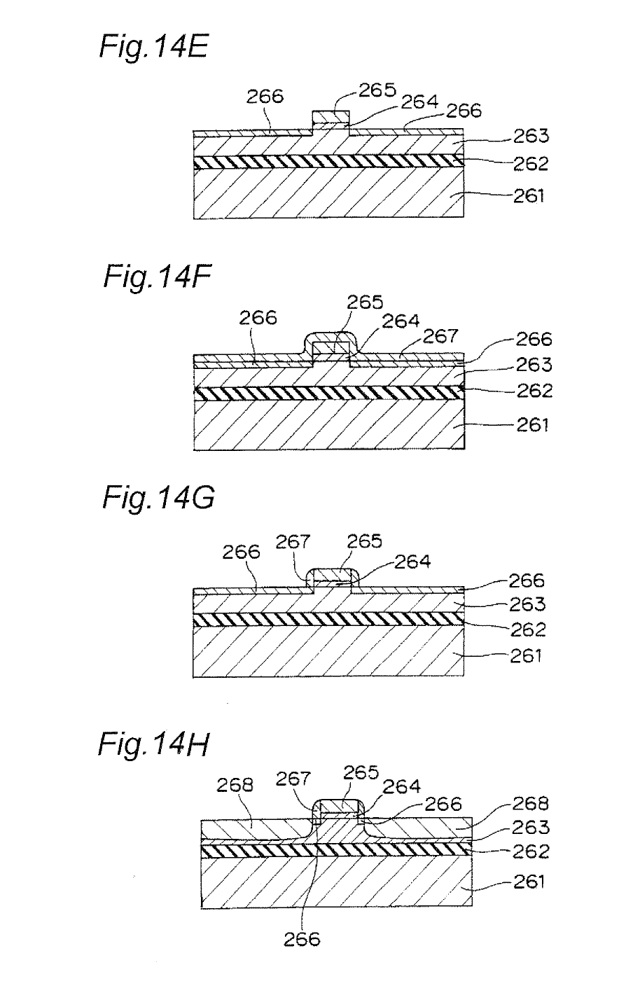

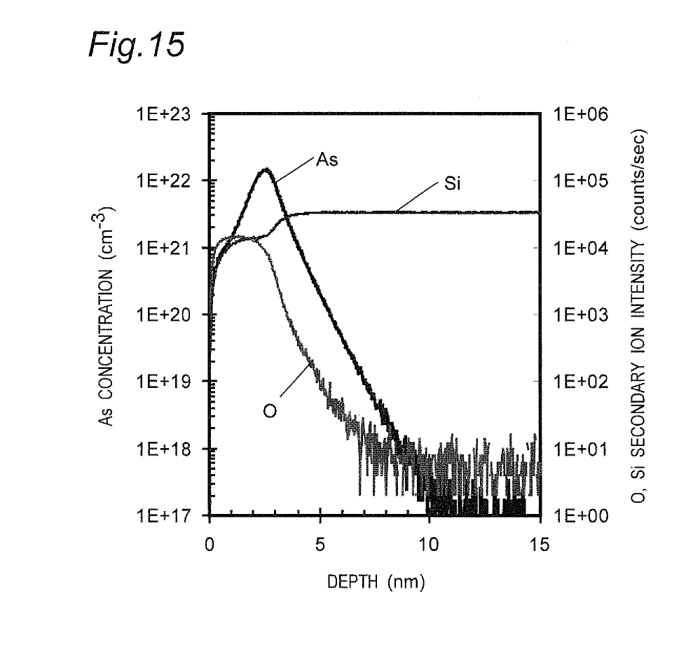

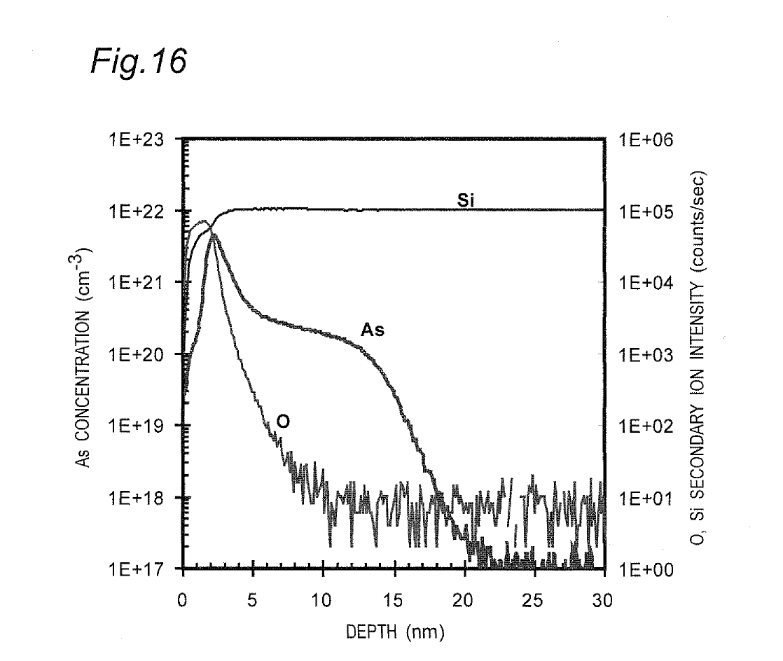

Moreover, as shown in FIG. 10, still another structure may be provided in which, by further not forming the dilution gas flow grooves 14k, 14s, and 16s, only the inner side suction grooves 14m, 14t, and 16t are formed so that the air trying to invade into the vacuum container 1 from the outside of the vacuum container 1 is sucked into the inner side suction groove 14m, 14t, or 1 6t and cannot invade into the vacuum container 1. The inner side suction grooves 14m, 14t, and 16t are not limited to the examples shown in FIG. 10, and may be formed on the side of a member that is opposed to and in contact with the member shown in FIG. 10.

Of course, all the suction grooves or the dilution gas flow grooves described in the above embodiments of the present invention are not intended to be limited to those examples illustrated in the drawings, and it is needless to say that the suction grooves or the dilution gas flow grooves may be formed on the side of the member that is opposed to and in contact with the member in which the suction grooves or the dilution gas flow grooves are formed.

In the second embodiment, as shown in FIGS. 9 and 10, the inner chamber 20 may not be provided.

Furthermore, there may be provided a structure in which the first embodiment and the second embodiment may be combined with each other. In the first embodiment or the second embodiment, the dilution gas may be neon.

In the above-mentioned various embodiments, by appropriately combining arbitrary embodiments, it is possible to obtain the respective effects.

### INDUSTRIAL APPLICABILITY

In the plasma doping apparatus in accordance with the present invention, the gas outside the vacuum container (for example, air) that tries to invade into the vacuum container through the sealing member tightly closing at least the coupling portion between the top plate and the vacuum container (moreover, the coupling portion between the upper chamber and the lower chamber of the vacuum container) is sucked so as to prevent the gas from flowing toward the substrate, or the gas flow is formed to prevent the gas outside the vacuum container (for example, air) from flowing toward the substrate so that the gas outside the vacuum container (for example, air) is prevented from exerting adverse effects to the process. This structure is in particular effectively used for manufacturing a semiconductor device having a shallow junction with a junction depth of 20 nm.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

1. A plasma doping apparatus comprising:
a vacuum container;
a top plate disposed on an upper end surface of the vacuum container;
a lower electrode disposed in the vacuum container and allowing a substrate to be placed thereon;
a high-frequency power supply that applies high-frequency power to the lower electrode;
a gas evacuation device that evacuates an inside of the vacuum container;
a gas supply device that supplies a process gas and a dilution gas into the vacuum container; and
a sealing member disposed between the upper end surface of the vacuum container and the top plate,
wherein on one of the upper end surface of the vacuum container and an contact surface of the top place to the vacuum chamber, a suction groove is disposed along an entire circumference of the vacuum container on an inner side to the vacuum container with respect to a position of the sealing member, and
a suction groove evacuation device connected to the suction groove is further included to suck a gas inside the suction groove to cause a pressure inside the suction groove to be made lower than a pressure inside the vacuum container.

2. The plasma doping apparatus according to claim 1, wherein the pressure inside the suction groove is reduced by at least one digit smaller than the pressure inside the vacuum container.

3. The plasma doping apparatus according to claim 1, further comprising:
a pressure detection device for the suction groove, which detects the pressure inside the suction groove;
a pressure detection device for the inside of the vacuum container, which detects the pressure inside the vacuum container; and
a control device that controls an operation of the gas evacuation device or the suction groove evacuation device such that the pressure inside the suction groove detected by the pressure detection device for a suction groove is made lower than the pressure inside the vacuum container detected by the pressure detection device for the vacuum container.

4. The plasma doping apparatus according claim 1, wherein, outside the suction groove disposed in one of the upper end surface of the vacuum container and the contact surface of the top place to the vacuum chamber being opposed to each other, a dilution gas flow groove is disposed independently from the suction groove along an entire circumference of an upper end portion of the vacuum container, and
the plasma doping apparatus further comprising a dilution gas supply device that supplies a dilution gas to the dilution gas flow groove.

5. The plasma doping apparatus according to claim 4, wherein, outside the dilution gas flow groove disposed in one of the upper end surface of the vacuum container and the contact surface of the top place to the vacuum chamber being opposed to each other, an outer side suction groove is disposed independently from the dilution gas flow groove along the entire circumference of the upper end portion of the vacuum container, and an inside of the outer side suction groove is sucked by the suction groove evacuation device.

6. A plasma doping apparatus comprising:
a vacuum container;
a top plate disposed on an upper end surface of the vacuum container;
a lower electrode disposed in the vacuum container and allowing a substrate to be placed thereon;
a high-frequency power supply that applies high-frequency power to the lower electrode;
a gas evacuation device that evacuates an inside of the vacuum container;
a gas supply device that supplies a process gas and a dilution gas into the vacuum container;
an inner chamber disposed in the vacuum container and along an inner wall surface of the vacuum container;
a dilution gas passage formed by the inner wall surface of the vacuum container and the inner chamber; and
a dilution gas supply device that supplies a dilution gas to the dilution gas passage from the top plate toward an evacuation side.

7. The plasma doping apparatus according to claim 6, wherein the vacuum container is configured by an upper chamber provided with the top plate on an upper end thereof and a lower chamber located under the upper chamber and coupled to the upper chamber.

8. The plasma doping apparatus according to claim 6, wherein the dilution gas passage has a gas flow passage of a length set to a mean free path or more.

9. The plasma doping apparatus according to claim 1, wherein the processing gas is AsH₃.

10. The plasma doping apparatus according to claim 1, wherein the dilution gas is helium, hydrogen, or neon.
